(19) United States
(12) Patent Application Publication
(10) Pub. No.: US 2024/0298459 A1
(43) Pub. Date: Sep. 5, 2024

(54) DISPLAY SUBSTRATE, ELECTROLUMINESCENT DEVICE AND MANUFACTURING METHOD THEREOF

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Dong LI, Beijing (CN); Zhuo LI, Beijing (CN)

(21) Appl. No.: 18/041,083

(22) PCT Filed: Feb. 18, 2022
(86) PCT No.: PCT/CN2022/076914

§ 371 Date: Feb. 9, 2023

(51) Int. Cl. H10K 50/16; H10K 50/115; H10K 50/15; H10K 59/122; H10K 59/35; H10K 71/00; H10K 102/00

(52) U.S. Cl. CPC H10K 50/166; H10K 50/115; H10K 50/156; H10K 59/122; H10K 59/353; H10K 71/00; H10K 2102/351

(57) ABSTRACT

The embodiments of the present disclosure provide a display substrate, an electroluminescent device and a manufacturing method thereof, the display substrate includes: a base substrate; a pixel definition layer, in which the pixel definition layer includes a plurality of openings, the openings correspond to a plurality of sub-pixel regions, the sub-pixel regions include a first sub-pixel region and a second sub-pixel region; a first color quantum dot layer, in the first sub-pixel region; a second color quantum dot layer, in the second sub-pixel region; a first auxiliary layer, at least including a first portion and a second portion spaced apart from each other, the first portion is on a side of the first color quantum dot layer away from the base substrate, the second portion is on a side of the second color quantum dot layer close to the base substrate.

### TECHNICAL FIELD

Embodiments of the present disclosure relate to a display substrate, an electroluminescent device and a manufacturing method thereof.

### BACKGROUND

As a new type of luminescent material, quantum dots (QDs) have the advantages of high photochromic purity, high luminous quantum efficiency, adjustable luminous color, and long service life, and become a research hotspot of a new luminescent material at present. Therefore, quantum dot light-emitting diodes (QLEDs) with the quantum dot materials as light-emitting layers have become the main direction of research on new display devices. With the continuous improvement of quantum efficiency, QLED devices can achieve a smaller area of luminescence, which is conducive to enabling display products to achieve higher resolution.

High-resolution AMQLED (active matrix quantum dot light-emitting diode) has also received more and more attention due to its potential advantages in wide color gamut, long life and other aspects. The research on the AMQLED is increasingly in-depth, and the quantum efficiency of the AMQLED is also continuously improved, basically reaching the level of industrialization. It has become the trend of future development to further adopt new processes and technologies to realize the industrialization of the AMQLED. Due to the characteristics of the quantum dot material itself, it is generally manufactured by a method of mask evaporation, a method of printing or a method of printing, but the method of mask evaporation has some defects such as difficult alignment, low yield, and inability to achieve smaller area luminescence. Therefore, the current demand for high-resolution display cannot be met.

### SUMMARY

At least one embodiment of the present disclosure provides a display substrate, an electroluminescent device and a manufacturing method thereof, the first auxiliary layer in the display substrate at least comprises a first portion and a second portion spaced apart from each other, the first portion of the first auxiliary layer is disposed on a side of the first color quantum dot layer away from the base substrate, and the second portion of the first auxiliary layer is disposed on a side of the second color quantum dot layer close to the base substrate, and the first auxiliary layer can avoid the second color quantum dot material formed later remaining on the first color quantum dot layer, thus avoiding the problem of color mixing, so as to improve the color gamut of the subsequently formed electroluminescent device.

At least one embodiment of the present disclosure provides a display substrate, and the display substrate comprises: a base substrate: a pixel definition layer, disposed on the base substrate, in which the pixel definition layer comprises a plurality of openings, the plurality of openings correspond to a plurality of sub-pixel regions, and the plurality of sub-pixel regions at least comprise a first sub-pixel region and a second sub-pixel region: a first color quantum dot layer, disposed in the first sub-pixel region: a second color quantum dot layer, disposed in the second sub-pixel region; and a first auxiliary layer, at least comprising a first portion and a second portion spaced apart from each other, in which the first portion is disposed on a side of the first color quantum dot layer away from the base substrate, and the second portion is disposed on a side of the second color quantum dot layer close to the base substrate.

For example, in the display substrate provided by at least one embodiment of the present disclosure, the first portion has a same thickness as that of the second portion, and a material of the first portion is the same as a material of the second portion.

For example, in the display substrate provided by at least one embodiment of the present disclosure, the material of the first portion and the material of the second portion are metal oxides.

For example, in the display substrate provided by at least one embodiment of the present disclosure, a surface roughness of each of the metal oxides is less than 3 nm.

For example, in the display substrate provided by at least one embodiment of the present disclosure, the first auxiliary layer further comprises a third portion, the third portion is disposed on a side of the pixel definition layer away from the base substrate, and the first portion, the second portion and the third portion are not connected to each other.

For example, the display substrate provided by at least one embodiment of the present disclosure further comprises a second auxiliary layer and a third color quantum dot layer disposed in a third sub-pixel region, and the second auxiliary layer is at least disposed on a side of the second color quantum dot layer away from the base substrate.

For example, in the display substrate provided by at least one embodiment of the present disclosure, a material of the first auxiliary layer is different from a material of the second auxiliary layer.

For example, in the display substrate provided by at least one embodiment of the present disclosure, the material of the first auxiliary layer comprises an electron-transporting type oxide, the material of the second auxiliary layer comprises a hole-transporting type oxide, at least a part of the first auxiliary layer is in contact with the first color quantum dot layer, and at least a part of the second auxiliary layer is in contact with the third color quantum dot layer.

For example, in the display substrate provided by at least one embodiment of the present disclosure, the first color quantum dot layer is a blue quantum dot layer, the second color quantum dot layer is one of a red quantum dot layer and a green quantum dot layer, and the third color quantum dot layer is the other one of the green quantum dot layer and the red quantum dot layer.

For example, in the display substrate provided by at least one embodiment of the present disclosure, each of a first color quantum dot comprised in the first color quantum dot layer, a second color quantum dot comprised in the second color quantum dot layer, and a third color quantum dot comprised in the third color quantum dot layer comprises a quantum dot body and a ligand connected to the quantum dot body, and a structure of the ligand is an A-B-C type; and A is an alignment group connected to the quantum dot body, B is a reactant after a photosensitive group is illuminated, and C is —COOH.

For example, in the display substrate provided by at least one embodiment of the present disclosure, each of a first color quantum dot comprised in the first color quantum dot layer, a second color quantum dot comprised in the second color quantum dot layer, and a third color quantum dot comprised in the third color quantum dot layer comprises a quantum dot body and a ligand connected to the quantum dot body, and a structure of the ligand is a mixture of an A-B type ligand and an A-C type ligand; and A is an alignment group connected to the quantum dot body, B is a reactant after a photosensitive group is illuminated, and C is —COOH.

For example, in the display substrate provided by at least one embodiment of the present disclosure, the second auxiliary layer at least comprises a fourth portion, a fifth portion and a sixth portion spaced apart from each other, and the fourth portion is disposed on a side of the first portion away from the base substrate, and is at least partially in contact with the first portion: the fifth portion is disposed on a side of the second color quantum dot layer away from the base substrate; and the sixth portion is disposed on a side of the third color quantum dot layer close to the base substrate.

For example, in the display substrate provided by at least one embodiment of the present disclosure, the second auxiliary layer further comprises a seventh portion spaced apart from the fourth portion, the fifth portion, and the sixth portion, and the seventh portion is disposed on a side of the third portion away from the base substrate, and is at least partially in contact with the third portion.

For example, in the display substrate provided by at least one embodiment of the present disclosure, the first auxiliary layer further comprises an eighth portion spaced apart from the first portion, the second portion, and the third portion, and the eighth portion is disposed on a side of the sixth portion close to the base substrate.

For example, in the display substrate provided by at least one embodiment of the present disclosure, materials of the first auxiliary layer and the second auxiliary layer both comprise at least one of an electron-transporting type oxide and a hole-transporting type oxide.

For example, in the display substrate provided by at least one embodiment of the present disclosure, the materials of the first auxiliary layer and the second auxiliary layer both comprise at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, in the display substrate provided by at least one embodiment of the present disclosure, the first auxiliary layer comprises a first layer structure and a second layer structure which are stacked, the first layer structure is on a side of the second layer structure close to the base substrate, and a material of the first layer structure comprises at least one of an electron-transporting type oxide and a hole-transporting type oxide; a general formula of the second layer structure comprises

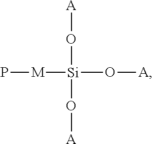

wherein A is —(CH₂)ₙCH₃, n is less than or equal to 4, M is —(CH₂)ₓ, and x is less than or equal to 6; and P comprises at least one of

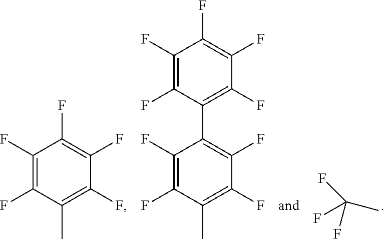

For example, in the display substrate provided by at least one embodiment of the present disclosure, the second auxiliary layer comprises a third layer structure and a fourth layer structure which are stacked, the third layer structure is on a side of the fourth layer structure close to the base substrate, and a material of the third layer structure comprises at least one of an electron-transporting type oxide and a hole-transporting type oxide; a general formula of the fourth layer structure comprises

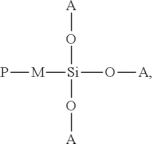

wherein A is —(CH₂)ₙCH₃, n is less than or equal to 4, M is —(CH₂)ₓ, and x is less than or equal to 6; and P comprises at least one of

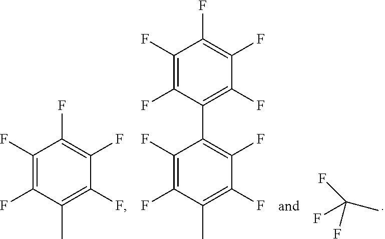

For example, in the display substrate provided by at least one embodiment of the present disclosure, the materials of the first layer structure and the third layer structure both comprise at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

At least one embodiment of the present disclosure further provides an electroluminescent device, and the electroluminescent device comprises any one of the display substrate mentioned above, and a first electrode and a first functional layer laminated on the base substrate, the first electrode is disposed on a side of the first functional layer close to the base substrate; and the first functional layer and the first electrode are laminated in the plurality of sub-pixel regions, and the first functional layer and the first electrode which are stacked are between the first color quantum dot layer and the base substrate, between the second color quantum dot layer and the base substrate, and between the third color quantum dot layer and the base substrate.

For example, in the electroluminescent device provided by at least one embodiment of the present disclosure, a material the first auxiliary layer is the same as a material of the first functional layer, and in a direction perpendicular to a main surface of the base substrate, a thickness of the first functional layer is 4 times to 5 times of a thickness of the first auxiliary layer.

For example, in the electroluminescent device provided by at least one embodiment of the present disclosure, a thickness of the first color quantum dot layer is 4 times to 5 times of a thickness of the first auxiliary layer.

At least one embodiment of the present disclosure further provides a manufacturing method of an electroluminescent device, and the manufacturing method comprises: providing a base substrate: forming a pixel definition layer on the base substrate, in which the pixel definition layer comprises a plurality of openings to form a plurality of sub-pixel regions spaced apart from each other, and the plurality of sub-pixel regions at least comprise a first sub-pixel region and a second sub-pixel region: forming a first color quantum dot layer in the first sub-pixel region; and forming a second color quantum dot layer in the second sub-pixel region: the manufacturing method further comprises: forming a first auxiliary layer after forming the first color quantum dot layer and before forming the second color quantum dot layer, in which the first auxiliary layer at least comprises a first portion and a second portion spaced apart from each other, the first portion is disposed on a side of the first color quantum dot layer away from the base substrate, and the second portion is disposed on a side of the second color quantum dot layer close to the base substrate.

For example, in the manufacturing method provided by at least one embodiment of the present disclosure, before forming the first color quantum dot layer, the manufacturing method further comprises forming a first functional layer on the base substrate, and in the second sub-pixel region and a third sub-pixel region, the first functional layer and the first auxiliary layer are attached to each other.

For example, in the manufacturing method provided by at least one embodiment of the present disclosure, a material of the first auxiliary layer comprises at least one of an electron-transporting type oxide and a hole-transporting type oxide, and the first auxiliary layer is formed by a method of magnetron sputtering.

For example, in the manufacturing method provided by at least one embodiment of the present disclosure, the material of the first auxiliary layer comprises at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, in the manufacturing method provided by at least one embodiment of the present disclosure, forming the first auxiliary layer comprises forming a first layer structure and a second layer structure which are stacked, the first layer structure is on a side of the second layer structure close to the base substrate, and forming the first layer structure comprises applying at least one of an electron-transporting type oxide and a hole-transporting type oxide on the base substrate by a method of magnetron sputtering; and forming the second layer structure comprises placing the base substrate formed with the first layer structure in a solution of a silane coupling agent for soaking, and the solution of the silane coupling agent comprises a first group containing a perfluoro terminal.

For example, in the manufacturing method provided by at least one embodiment of the present disclosure, the material of the first layer structure comprises at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, the manufacturing method provided by at least one embodiment of the present disclosure, further comprises: forming a second auxiliary layer at least on a side of the second color quantum dot layer away from the base substrate; and forming a third color quantum dot layer on a side of the second auxiliary layer away from the base substrate and in the third sub-pixel region, and a material of the first auxiliary layer is different from a material of the second auxiliary layer.

For example, in the manufacturing method provided by at least one embodiment of the present disclosure, the material of the second auxiliary layer comprises at least one of an electron-transporting type oxide and a hole-transporting type oxide, and the second auxiliary layer is formed by a method of magnetron sputtering.

For example, in the manufacturing method provided by at least one embodiment of the present disclosure, the material of the second auxiliary layer comprises at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, in the manufacturing method provided by at least one embodiment of the present disclosure, forming the second auxiliary layer comprises forming a third layer structure and a fourth layer structure which are stacked, the third layer structure is on a side of the fourth layer structure close to the base substrate, and forming the third layer structure comprises applying at least one of an electron-transporting type oxide and a hole-transporting type oxide on the base substrate by a method of magnetron sputtering; and forming the fourth layer structure comprises placing the base substrate formed with the third layer structure in a solution of a silane coupling agent for soaking, and the solution of the silane coupling agent comprises a third group containing a perfluoro terminal.

For example, in the manufacturing method provided by at least one embodiment of the present disclosure, the material of the third layer structure comprises at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, in the manufacturing method provided by at least one embodiment of the present disclosure, forming the first color quantum dot layer comprises: depositing a first color quantum dot material on the first functional layer, and crosslinking and developing the first color quantum dot material in the first sub-pixel region, to form the first color quantum dot layer: forming the second color quantum dot layer comprises: depositing a second color quantum dot material on the first functional layer, and crosslinking and developing the second color quantum dot material in the second sub-pixel region, to form the second color quantum dot layer; and forming the third color quantum dot layer comprises: depositing a third color quantum dot material on the first functional layer, and crosslinking and developing the third color quantum dot material in the third sub-pixel region, to form the third color quantum dot layer.

For example, in the manufacturing method provided by at least one embodiment of the present disclosure, the material of the first auxiliary layer comprises an electron-transporting type oxide, the material of the second auxiliary layer comprises a hole-transporting type oxide, at least a part of the first auxiliary layer is in contact with the first color quantum dot layer, and at least a part of the second auxiliary layer is in contact with the third color quantum dot layer.

For example, in the manufacturing method provided by at least one embodiment of the present disclosure, after forming the first color quantum dot layer, the second color quantum dot layer and the third color quantum dot layer, the manufacturing method further comprises sequentially forming a second functional layer and a third functional layer on a side of the first color quantum dot layer, the second color quantum dot layer and the third color quantum dot layer away from the base substrate.

For example, the manufacturing method provided by at least one embodiment of the present disclosure, further comprises: forming a first electrode on the base substrate before forming the first functional layer, in which a material of the first electrode comprises a transparent conductive metal oxide or a conductive polymer; and forming a second electrode on a side of the third functional layer away from the base substrate, in which a material of the second electrode comprises a conductive metal or a conductive metal oxide.

For example, in the manufacturing method provided by at least one embodiment of the present disclosure, the first auxiliary layer and the second auxiliary layer are sequentially formed on a surface of the pixel definition layer away from the base substrate.

### BRIEF DESCRIPTION OF THE DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1 is a schematic diagram of a process of patterning a quantum dot layer;

FIG. 2 is a quantum dot pattern formed in an actual process in FIG. 1;

FIG. 3 is a schematic diagram of a cross-sectional structure of a display substrate provided by at least one embodiment of the present disclosure:

FIG. 4 is a schematic diagram of a cross-sectional structure of another display substrate provided by at least one embodiment of the present disclosure:

FIG. 5 is a schematic diagram of a cross-sectional structure of a first auxiliary layer with a double-layer structure provided by at least one embodiment of the present disclosure:

FIG. 6 is a schematic diagram of a cross-sectional structure of a second auxiliary layer with a double-layer structure, provided by at least one embodiment of the present disclosure:

FIG. 7 is a schematic diagram of a cross-sectional structure of still another display substrate provided by at least one embodiment of the present disclosure:

FIG. 8 is a schematic diagram of a cross-sectional structure of an electroluminescent device provided by at least one embodiment of the present disclosure;

FIG. 9 is a schematic diagram of a cross-sectional structure of another electroluminescent device provided by at least one embodiment of the present disclosure:

FIG. 10 is a flowchart of a manufacturing process of an electroluminescent device provided by at least one embodiment of the present disclosure:

FIG. 11 is a flowchart of a manufacturing process of another electroluminescent device provided by at least one embodiment of the present disclosure:

FIG. 12 is a schematic diagram of a manufacturing process of an electroluminescent device provided by at least one embodiment of the present disclosure:

FIG. 13 is a graph of emission peaks of blank glass, blank glass with quantum dots (without MPA ligands), blank glass with zinc oxide and quantum dots (without MPA ligands) and blank glass with zinc oxide and quantum dots (with MPA ligands) under the irradiation of 400 nm excitation light:

FIG. 14 is a schematic diagram of an emission peak formed by red quantum dots (without MPA ligands) under the irradiation of 400 nm excitation light after sputtering ZnO and after development:

FIG. 15 is a schematic diagram of an emission peak formed by red quantum dots (with MPA ligands) under the irradiation of 400 nm excitation light after sputtering ZnO, developing (washing off the red quantum dots), and then depositing green quantum dots:

FIG. 16 is a schematic diagram of an emission peak formed by green quantum dots (with MPA ligands) under the irradiation of 400 nm excitation light after sputtering ZnO and after development; and

FIG. 17 is a schematic diagram of green quantum dots emitting light after sputtering ZnO, depositing, exposure crosslinking, and then depositing red quantum dots (without MPA ligands) and developing (washing off the red quantum dots).

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

In the manufacturing process of quantum dot electroluminescent devices, patterning of a quantum dot layer is mainly realized by a process of inkjet printing, but limited by the inkjet printing equipment, the resolution of the formed patterned quantum dot layer is limited within 200 ppi. In addition, when using the inkjet printing process to realize the patterning of the quantum dot layer, before depositing each functional layer, a pixel definition layer needs to be manufactured first, and the quantum dot ink in each functional layer has the problem of climbing on the pixel definition layer, and even the quantum dot ink will climb to a platform region on the top of the pixel definition layer, which greatly affects the morphology and thickness uniformity of the formed quantum dot film, and affects the life of the quantum dot electroluminescent device and the uniformity of output light, and further affects the mass production of subsequent quantum dot electroluminescent device. This problem is more obvious especially for display panels with high resolution. Therefore, it is necessary to study a patterning method of the quantum dot layer to improve the resolution of the quantum dot electroluminescent device.

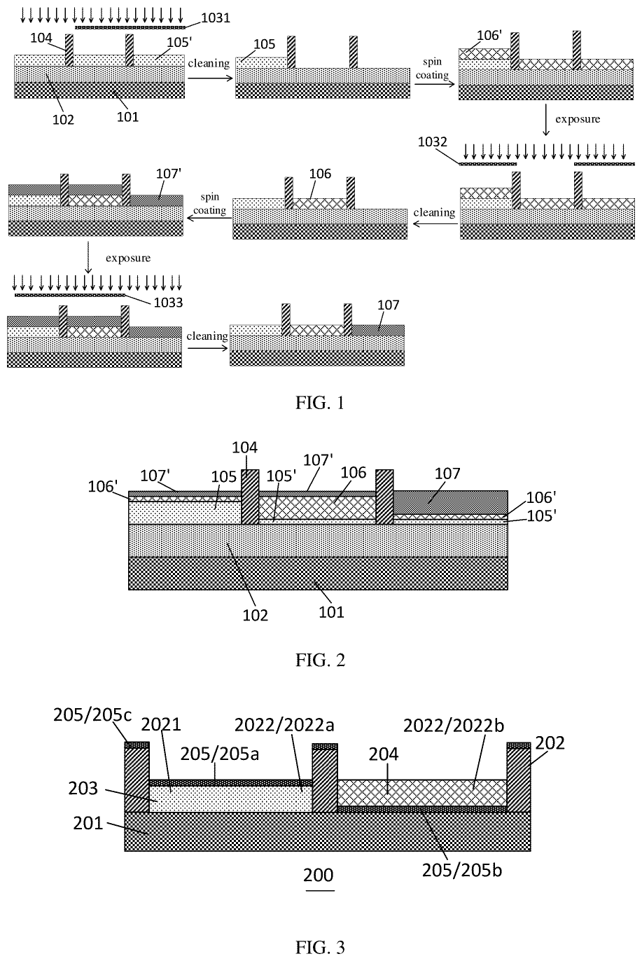

For example, full-color patterning of the quantum dot electroluminescent device may be achieved directly by photolithography, but this process also has disadvantages, that is, quantum dots of different colors will remain in each pixel region, resulting in the problem of color mixing. For example, FIG. 1 is a schematic diagram of a process of patterning a quantum dot layer. As illustrated in FIG. 1, a base substrate 101 is provided, and a first electrode 102 is formed on the base substrate 101. A pixel definition layer 104 is formed on a side of the base substrate 101 on which the first electrode 102 is formed, the pixel definition layer 104 includes a plurality of openings to form a plurality of sub-pixel regions, and a red quantum dot material is applied to each sub-pixel region to form a red quantum dot film layer 105′. The process of patterning the red quantum dot film layer 105′ includes: using a first mask 1031 to block the sub-pixel region in the middle region and the rightmost sub-pixel region, so that the light irradiates to the leftmost sub-pixel region and the red quantum dot material in the leftmost sub-pixel region undergoes a cross-linking reaction, that is, the exposure process of the red quantum dot film layer 105′ is completed, and the red quantum dot material that has not undergone the cross-linking reaction is cleaned to remove the red quantum dot material in the sub-pixel region in the middle region and in the rightmost sub-pixel region, that is, forming a red quantum dot pattern 105. A green quantum dot material is applied to each sub-pixel region to form a green quantum dot film layer 106′, and the process of patterning the green quantum dot film layer 106′ includes: using a second mask 1032 to block the leftmost sub-pixel region and the rightmost sub-pixel region, so that the light irradiates to the sub-pixel region in the middle region and the green quantum dot material in the sub-pixel region undergoes a cross-linking reaction, that is, the exposure process of the green quantum dot film layer 106′ is completed, and the green quantum dot material that has not undergone the cross-linking reaction is cleaned to remove the green quantum dot material in the leftmost sub-pixel region and in the rightmost sub-pixel region, that is, forming a green quantum dot pattern 106. A blue quantum dot material is applied to each sub-pixel region to form a blue quantum dot film layer 107′, and the process of patterning the blue quantum dot film layer 107′ includes: using a third mask 1033 to block the leftmost sub-pixel region and the sub-pixel region in the middle region, so that the light irradiates to the sub-pixel region in the rightmost and the blue quantum dot material in the rightmost sub-pixel region undergoes a cross-linking reaction, that is, the exposure process of the blue quantum dot film layer 107′ is completed, and the blue quantum dot material that has not undergone the cross-linking reaction is cleaned to remove the blue quantum dot material in the sub-pixel region in the leftmost and in the sub-pixel region in the middle region, that is, forming a blue quantum dot pattern 107.

It should be noted that the process diagram illustrated in FIG. 1 is an ideal process manufacturing flowchart, in which the quantum dots that have not undergone the cross-linking reaction are removed during each step of the cleaning process. However, in an actual manufacturing process, there is always a problem that the quantum dots that have not undergone the crosslinking reaction are not cleaned cleanly, that is, there will be residual quantum dots that have not undergone the crosslinking reaction. For example, the red quantum dots remain in the sub-pixel region in the middle region and in the sub-pixel region in the rightmost: the green quantum dots remain in the sub-pixel region in the leftmost and in the sub-pixel region in the rightmost; and the blue quantum dots remain in the sub-pixel region in the middle region and in the sub-pixel region in the leftmost. For example, FIG. 2 is a quantum dot pattern formed in an actual process in FIG. 1. As illustrated in FIG. 2, the green quantum dot material and the blue quantum dot material remain on a side of the red quantum dot pattern 105 away from the base substrate 101; the red quantum dot material remains on a side of the green quantum dot pattern 106 close to the base substrate 101; the blue quantum dot material remains on a side of the green quantum dot pattern 106 away from the base substrate 101; and the green quantum dot material and the red quantum dot material remain on a side of the blue quantum dot pattern 107 close to the base substrate 101.

In addition, the quantum dot pattern can also be formed by using an indirect photolithography method, that is, a sacrificial layer is used to realize the patterning of the quantum dot luminescent material. Specifically, the indirect photolithography method includes forming the sacrificial layer in the region where the quantum dot luminescent material needs to be removed before forming the quantum dot luminescent material, and then patterning the quantum dot luminescent material with sacrificial layer elution method. A similar phenomenon also exists in the indirect photolithography method, in which the green quantum dot material and the blue quantum dot material remain on a side of the red quantum dot pattern away from the base substrate; the red quantum dot material remains on a side of the green quantum dot pattern close to the base substrate; the blue quantum dot material remains on a side of the green quantum dot pattern away from the base substrate; and the green quantum dot material and the red quantum dot material remain on a side of the blue quantum dot pattern close to the base substrate. That is, both the direct photolithography method and the indirect photolithography method have the problem that the quantum dot material applied later remains on the previously formed quantum dot pattern.

The inventor(s) of the present disclosure notes that a first auxiliary layer can be formed on a surface of the red quantum dot pattern that has undergone the cross-linking reaction, so that the green quantum dot material subsequently formed on it can be easily washed off, and a second auxiliary layer can be formed on a surface of the green quantum dot pattern that has undergone the cross-linking reaction, so that the blue quantum dot material subsequently formed on it can be easily washed off, thereby reducing the phenomenon of color mixing.

At least one embodiment of the present disclosure provides a quantum dot electroluminescent device, and the quantum dot electroluminescent device includes: a base substrate; a pixel definition layer disposed on the base substrate, in which the pixel definition layer includes a plurality of openings, the plurality of openings correspond to a plurality of sub-pixel regions, and the plurality of sub-pixel regions at least include a first sub-pixel region and a second sub-pixel region; a first color quantum dot layer is disposed in the first sub-pixel region; a second color quantum dot layer is disposed in the second sub-pixel region; and a first auxiliary layer at least includes a first portion and a second portion spaced apart from each other, in which the first portion is disposed on a side of the first color quantum dot layer away from the base substrate, and the second portion is disposed on a side of the second color quantum dot layer close to the base substrate. The first auxiliary layer can prevent the second color quantum dot material formed later from remaining on the first color quantum dot layer, thereby avoiding the problem of color mixing and improving the color gamut of the quantum dot electroluminescent device.

For example, FIG. 3 is a schematic diagram of a cross-sectional structure of a display substrate provided by at least one embodiment of the present disclosure. As illustrated in FIG. 3, the display substrate 200 includes a base substrate 201 and a pixel definition layer 202 disposed on the base substrate 201. The pixel definition layer 202 includes a plurality of openings 2021, and the plurality of openings 2021 correspond to a plurality of sub-pixel regions 2022, for example, one opening 2021 corresponds to a sub-pixel region 2022. That is, quantum dot layers of different colors are respectively formed in the plurality of openings 2021 to set the plurality of openings 2021 as the plurality of sub-pixel regions 2022, and the plurality of sub-pixel regions 2022 are distinguished according to the different colors of the quantum dot layers formed in the openings 2021. The plurality of sub-pixel regions 2022 at least include a first sub-pixel region 2022a and a second sub-pixel region 2022b, the first color quantum dot layer 203 is disposed in the first sub-pixel region 2022a, and the second color quantum dot layer 204 is disposed in the second sub-pixel region 2022b. The first auxiliary layer 205 at least includes a first portion 205a and a second portion 205b spaced apart from each other, the first portion 205a is disposed on a side of the first color quantum dot layer 203 away from the base substrate 201, and the second portion 205b is disposed on a side of the second color quantum dot layer 204 close to the base substrate 201. In the structure illustrated in FIG. 3, the first auxiliary layer 205 is also disposed on the side of a portion of the pixel definition layer 202 except the opening away from the base substrate 201, that is, the first auxiliary layer 205 is formed as a whole layer. However, the first auxiliary layer 205 of each sub-pixel region is disconnected from each other due to the existence of segment difference caused by the openings of the pixel definition layer.

For example, in one example, as illustrated in FIG. 3, because the portion of the pixel definition layer 202 except the opening 2021 has a segment difference from the opening 2021, the first portion 205a and the second portion 205b are spaced apart from each other by the portion of the pixel definition layer 202 except the opening 2021.

For example, in one example, the material of the first portion 205a and the material of the second portion 205b are metal oxide. For example, a surface roughness of the metal oxide is less than 3 nm. It should be noted that the surface roughness refers to RMS roughness.

For example, in one example, as illustrated in FIG. 3, the first auxiliary layer 205 further includes a third portion 205c, the third portion 205c is disposed on a side of the pixel definition layer 202 away from the base substrate 201, and the first portion 205a, the second portion 205b and the third portion 205c are not connected to each other.

For example, in one example, the first auxiliary layer 205 has characteristics of electron transmission and/or electron blocking, and the connection force between the first auxiliary layer 205 and an uncrosslinked quantum dot material on it is weak, which makes the uncrosslinked quantum dot material easier to be washed off, thereby preventing the second color quantum dot material formed later from remaining on the first color quantum dot layer, thereby avoiding the problem of color mixing to improve the color gamut of a subsequently formed electroluminescent device.

For example, both the thickness ratio of the first auxiliary layer 205 to the first color quantum dot layer 203 and the thickness ratio of the first auxiliary layer 205 to the second color quantum dot layer 204 may be 0.1 to 0.5, for example, the thickness of the first auxiliary layer 205 is 5 nm to 10 nm, and the thickness of the first auxiliary layer 205 is 20 nm to 50 nm.

For example, it should be noted that the quantum dot layers of various colors include quantum dots of different colors, and the quantum dots of different colors may be semiconductor nanocrystals, and may have various shapes, such as spheres, cones, multi-armed and/or cubic nanoparticles, nanotubes, nanowires, nanofibers, nanoplate particles, quantum rods, or quantum sheets. Here, the quantum rod may be a quantum dot having an aspect ratio (length-to-diameter ratio) (length:width ratio) of greater than about 1, for example, greater than or equal to about 2, greater than or equal to about 3, or greater than or equal to about 5. For example, the quantum rod may have an aspect ratio of less than or equal to about 50, less than or equal to about 30, or less than or equal to about 20.

For example, the quantum dot may have a particle diameter (average maximum particle length for non-spherical shapes) of, for example, about 1 nm to about 100 nm, about 1 nm to about 80 nm, about 1 nm to about 50 nm, or about 1 nm to 20 nm.

For example, the energy bandgap of the quantum dot can be controlled according to the size and composition of the quantum dot, and thus the emission wavelength can be controlled. For example, the quantum dot may have a narrow energy bandgap and thus be configured to emit light in a relatively long wavelength region as the size of the quantum dot increases, and the quantum dot may have a wide energy bandgap and thus be configured to emit light in a relatively short wavelength region as the size of the quantum dot decreases. For example, the quantum dot may be configured to emit light in a predetermined wavelength region of the visible light region according to the size and/or composition of the quantum dot. For example, the quantum dot may be configured to emit blue light, red light, or green light, the blue light may have a peak emission wavelength (λmax), for example, in a range from about 430 nm to about 480 nm, the red light may have a peak emission wavelength (λmax), for example, in a range from about 600 nm to about 650 nm, and green light may have a peak emission wavelength (λmax), for example, in a range from about 520 nm to about 560 nm.

For example, the average particle size of the quantum dot configured to emit blue light may be, for example, less than or equal to about 4.5 nm, and, for example, less than or equal to about 4.3 nm, less than or equal to about 4.2 nm, less than or equal to about 4.1 nm, or less than or equal to about 4.0 nm. Within the range, for example, the average particle size of the quantum dot may be from about 2.0 nm to about 4.5 nm, such as from about 2.0 nm to about 4.3 nm, from about 2.0 nm to about 4.2 nm, from about 2.0 nm to about 4.1 nm, or from about 2.0 nm to about 4.0 nm.

The quantum dot may have a quantum yield, for example, greater than or equal to about 10%, greater than or equal to about 20%, greater than or equal to about 30%, greater than or equal to about 50%, greater than or equal to about 60%, greater than or equal to about 70%, or greater than or equal to about 90%.

The quantum dot may have a relatively narrow half width (FWHM). Here, the FWHM is a width corresponding to a wavelength half of a peak absorption point, and in the case where the FWHM is narrow, the quantum dot can be configured to emit light in a narrow wavelength region, and a high color purity can be obtained. The quantum dot may have a FWHM, for example, less than or equal to about 50 nm, less than or equal to about 49 nm, less than or equal to about 48 nm, less than or equal to about 47 nm, less than or equal to about 46 nm, less than or equal to about 45 nm, less than or equal to about 44 nm, less than or equal to about 43 nm, less than or equal to about 42 nm, less than or equal to about 41 nm, less than or equal to about 40 nm, less than or equal to about 39 nm, less than or equal to about 38 nm, less than or equal to about 37 nm, less than or equal to about 36 nm, less than or equal to about 35 nm, less than or equal to about 34 nm, less than or equal to about 33 nm, less than or equal to about 32 nm, less than or equal to about 31 nm, less than or equal to about 30 nm, less than or equal to about 29 nm, or less than or equal to about 28 nm. Within the range, the quantum dot may have a FWHM, for example, from about 2 nm to about 49 nm, from about 2 nm to about 48 nm, from about 2 nm to about 47 nm, from about 2 nm to about 46 nm, from about 2 nm to about 45 nm, from about 2 nm to about 44 nm, from about 2 nm to about 43 nm, from about 2 nm to about 42 nm, from about 2 nm to about 41 nm, from about 2 nm to about 40 nm, from about 2 nm to about 39 nm, from about 2 nm to about 38 nm, from about 2 nm to about 37 nm, from about 2 nm to about 36 nm, from about 2 nm to about 35 nm, from about 2 nm to about 34 nm, from about 2 nm to about 33 nm, from about 2 nm to about 32 nm, from about 2 nm to about 31 nm, from about 2 nm to about 30 nm, from about 2 nm to about 29 nm, or from about 2 nm to about 28 nm.

For example, the quantum dot may include a semiconductor compound made of the elements in the group II and the group VI, a semiconductor compound made of the elements in the group III and the group V, a semiconductor compound made of the elements in the group IV and the group VI, a semiconductor made of the element in the group IV, a semiconductor compound made of the elements in the group I, the group III and the group VI, a semiconductor compound made of the elements in the group I, the group II, the group IV, and the group VI, a semiconductor compound made of the elements in the group II, the group III and the group V, or a combination thereof. The semiconductor compound made of the elements in the group II and the group VI may be selected, for example, from: a binary compound such as CdSe, CdTe, ZnS, ZnSe, ZnTe, ZnO, HgS, HgSe, HgTe, MgSe, MgS, or a mixture thereof: a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, or a mixture thereof, but not limited thereto. The semiconductor compound made of the elements in the group III and the group V may be selected, for example, from: a binary compound such as GaN, GaP, GaAs, GaSb, AlN, AIP, AlAs, AlSb, InN, InP, InAs, InSb, or a mixture thereof; a ternary compound such as GaNP, GaNAs, GaNSb, GaPAs, GaPSb, AlNP, AlNAs, AlNSb, AlPAs, AlPSb, InNP, InNAs, InNSb, InPAs, InPSb, or a mixture thereof; and a quaternary compound such as GaAINP, GaAINAs, GaAINSb, GaAlPAs, GaAlPSb, GaInNP, GaInNAs, GaInNSb, GalnPAs, GaInPSb, InAINP, InAINAs, InAINSb, InAlPAs, InAlPSb, or a mixture thereof, but not limited thereto. The semiconductor compound made of the elements in the group IV and the group VI may be selected, for example, from: a binary compound such as SnS, SnSe, SnTe, PbS, PbSe, PbTe, or a mixture thereof: a ternary compound such as SnSeS, SnSeTe, SnSTe, PbSeS, PbSeTe, PbSTe, SnPbS, SnPbSe, SnPbTe, or a mixture thereof; and a quaternary compound such as SnPbSSe, SnPbSeTe, SnPbSTe, or a mixture thereof, but not limited thereto. The semiconductor made of the element in the group IV may be selected, for example, from: an elemental (unary) semiconductor such as Si, Ge, or a mixture thereof; and a binary semiconductor compound such as SiC, SiGe, or a mixture thereof, but not limited thereto. The semiconductor compound made of the elements in the group I, the group III and the group VI may be, for example, CuInSe₂, CuInS₂, CuInGaSe, CuInGaS, or a mixture thereof, but not limited thereto. The semiconductor compound made of the elements in the group I, the group II, the group IV and the group VI may be, for example, CuZnSnSe, CuZnSnS, or a mixture thereof, but not limited thereto. The semiconductor compound made of the elements in the group II, the group III and the group V may include, for example, InZnP, but not limited thereto.

The quantum dots may have a substantially uniform concentration distribution or a locally varying concentration distribution, and the quantum dots include the elemental semiconductor, the binary semiconductor compound, the ternary semiconductor compound, or the quaternary semiconductor compound.

For example, the quantum dots may include cadmium(Cd)-free quantum dots. The cadmium-free quantum dots are quantum dots that do not include cadmium (Cd). Cadmium (Cd) may cause serious environmental/health problems, Cadmium is an element restricted under the Restriction of Hazardous Substances (RoHS) in many countries, and thus non-cadmium-based quantum dots may be effectively used.

As an implementation manner, the quantum dot may be a semiconductor compound including at least one of zinc (Zn), tellurium (Te) and selenium (Se). For example, the quantum dot may be a Zn—Te semiconductor compound, a Zn—Se semiconductor compound, and/or a Zn—Te—Se semiconductor compound. For example, the amount of tellurium (Te) in the Zn—Te—Se semiconductor compound may be smaller than the amount of selenium (Se). The semiconductor compound may have a peak emission wavelength (λmax) in a wavelength region of less than or equal to about 480 nm, for example, from about 430 nm to about 480 nm, and may be configured to emit blue light.

For example, the quantum dot may be a semiconductor compound including at least one of indium (In), zinc (Zn) and phosphorus (P). For example, the quantum dot may be an In—P semiconductor compound and/or an In—Zn—P semiconductor compound. For example, in the In—Zn—P semiconductor compound, a molar ratio of zinc (Zn) to indium (In) may be greater than or equal to about 25. The semiconductor compound may have a peak emission wavelength (λmax) in a wavelength region of less than about 700 nm, for example, from about 600 nm to about 650 nm, and may be configured to emit red light.

The quantum dots may have a core-shell structure in which one quantum dot surrounds another quantum dot. For example, the core and the shell of the quantum dot may have an interface, and an element of at least one of the core or the shell in the interface may have a concentration gradient, in which the concentration of the element of the shell decreases toward the core. For example, the material composition of the shell of the quantum dot has a higher energy bandgap than the material composition of the core of the quantum dot, and thus the quantum dots may exhibit a quantum confinement effect.

The quantum dots may have one quantum dot core and multilayers of quantum dot shells surrounding the quantum dot core. Here, the multilayers of the quantum dot shells have at least two shells, in which each of the shells may be of single composition, alloy, and/or a composition has a concentration gradient.

For example, a shell of the multilayers of the quantum dot shells away from the quantum dot core may have a higher energy bandgap than a shell of the multilayers of the quantum dot shells close to the quantum dot core, and thus the quantum dots may exhibit a quantum confinement effect.

For example, the quantum dot having a core-shell structure may, for example, include: a core including a first semiconductor compound, in which the first semiconductor compound includes at least one of zinc (Zn), tellurium (Te) and selenium (Se); and a shell including a second semiconducting compound disposed on at least a portion of the core and having a composition different from that of the core.

For example, the first semiconductor compound may be a Zn—Te—Se based semiconductor compound including zinc (Zn), tellurium (Te) and selenium (Se), for example, may be a Zn—Se based semiconductor compound including a small amount of tellurium (Te), for example, may be a semiconductor compound represented by ZnTexSel-x, in which x is greater than about 0 and less than or equal to 0.05.

For example, in the first semiconductor compound based on Zn—Te—Se, the molar amount of zinc (Zn) may be higher than the molar amount of selenium (Se), and the molar amount of selenium (Se) may be higher than the molar amount of tellurium (Te). For example, in the first semiconductor compound, the molar ratio of tellurium (Te) to selenium (Se) may be less than or equal to about 0.05, less than or equal to about 0.049, less than or equal to about 0.048, less than or equal to about 0.047, less than or equal to about 0.045, less than or equal to about 0.044, less than or equal to about 0.043, less than or equal to about 0.042, less than or equal to about 0.041, less than or equal to about 0.04, less than or equal to about 0.039, less than or equal to about 0.035, less than or equal to about 0.03, less than or equal to about 0.029, less than or equal to about 0.025, less than or equal to about 0.024, less than or equal to about 0.023, less than or equal to about 0.022, less than or equal to about 0.021, less than or equal to about 0.02, less than or equal to about 0.019, less than or equal to about 0.018, less than or equal to about 0.017, less than or equal to about 0.016, less than or equal to about 0.015, less than or equal to about 0.014, less than or equal to about 0.013, less than or equal to about 0.012, less than or equal to about 0.011, or less than or equal to about 0.01. For example, in the first semiconductor compound, the molar ratio of tellurium (Te) to zinc (Zn) may be less than or equal to about 0.02, less than or equal to about 0.019, less than or equal to about 0.018, less than or equal to about 0.017, less than or equal to about 0.016, less than or equal to about 0.015, less than or equal to about 0.014, less than or equal to about 0.013, less than or equal to about 0.012, less than or equal to about 0.011, or less than or equal to about 0.010.

The second semiconductor compound may include, for example, a semiconductor compound made of the elements in the group II and the group VI, a semiconductor compound made of the elements in the group III and the group V, a semiconductor compound made of the elements in the group IV and the group VI, a semiconductor compound made of the element in the group IV, a semiconductor compound made of the elements in the group I, the group III, and the group VI, a semiconductor compound made of the elements in the group I, the group II, the group IV, and the group VI, a semiconductor compound made of the elements in the group II, the group III, and the group V, or a combination thereof. Examples of the semiconductor compound made of the elements in the group II and the group VI, the semiconductor compound made of the elements in the group III and the group V, the semiconductor compound made of the elements in the group IV and the group VI, the semiconductor compound made of the element in the group IV, the semiconductor compound made of the elements in the group I, the group III, and the group VI, the semiconductor compound made of the elements in the group I, the group II, the group IV, the group VI, and the semiconductor compound made of the elements in the group II, the group III, and the group V are the same as the descriptions mentioned above.

For example, the second semiconductor compound may include zinc (Zn), selenium (Se), and/or sulfur (S). For example, the shell may include ZnSeS, ZnSe, ZnS, or a combination thereof. For example, the shell may include at least one inner shell disposed close to the core and an outermost shell disposed at the outermost side of the quantum dot. The inner shell may include ZnSeS, ZnSe, or a combination thereof, and the outermost shell may include ZnS. For example, the shell may have a concentration gradient of a constituent, and for example the amount of sulfur (S) may increase as the sulfur leaves the core.

For example, the quantum dot having a core-shell structure may, for example, include: a core including a third semiconductor compound, in which the third semiconductor compound includes at least one of indium (In), zinc (Zn) and phosphorus (P); and a shell including a fourth semiconducting compound disposed on at least a portion of the core and having a composition different from that of the core.

In the third semiconductor compound based on In—Zn—P, the molar ratio of zinc (Zn) to indium (In) may be greater than or equal to about 25. For example, in the third semiconductor compound based on In—Zn—P, the molar ratio of zinc (Zn) to indium (In) may be greater than or equal to about 28, greater than or equal to about 29, or greater than or equal to about 30. For example, in the third semiconductor compound based on In—Zn—P, the molar ratio of zinc (Zn) to indium (In) may be less than or equal to about 55, such as less than or equal to about 50, less than or equal to about 45, less than or equal to about 40, less than or equal to about 35, less than or equal to about 34, less than or equal to about 33, or less than or equal to about 32.

The fourth semiconductor compound may include, for example, a semiconductor compound made of the elements in the group II and the group VI, a semiconductor compound made of the elements in the group III and the group V, a semiconductor compound made of the elements in the group IV and the group VI, a semiconductor compound made of the element in the group IV, a semiconductor compound made of the elements in the group I, the group III, and the group VI, a semiconductor compound made of the elements in the group I, the group II, the group IV, and the group VI, a semiconductor compound made of the elements in the group II, the group III and the group V, or a combination thereof. Examples of a semiconductor compound made of the elements in the group II and the group VI, a semiconductor compound made of the elements in the group III and the group V, a semiconductor compound made of the elements in the group IV and the group VI, a semiconductor compound made of the element in the group IV, a semiconductor compound made of the elements in the group I, the group III and the group VI, a semiconductor compound made of the elements in the group I, the group II, the group IV and the group VI, and a semiconductor compound made of the elements in the group II, the group III and the group V are the same as the descriptions mentioned above.

For example, the fourth semiconductor compound may include zinc (Zn), sulfur (S) and selenium (Se). For example, the shell may include ZnSeS, ZnSe, ZnS, or a combination thereof. For example, the shell may include at least one inner shell disposed close to the core and an outermost shell disposed at the outermost side of the quantum dot. At least one of the inner shell and the outermost shell may include the fourth semiconductor compound ZnS, ZnSe, or ZnSeS.

The light emitting layer may have the following thickness: for example, from about 5 nm to about 200 nm, within the range, for example, from about 10 nm to about 150 nm, for example, from about 10 nm to about 100 nm, for example, from about 10 nm to about 50 nm. Quantum dots QDs contained in the light emitting layer EML may be laminated into one or more layers, such as two layers. However, the implementation scheme of the concept of the present disclosure is not limited to this, and the quantum dots QDs may be laminated into one to ten layers. The quantum dots QDs may be laminated into any suitable number of layers depending on the kind (or type) of quantum dots QDs being used and the desired emission wavelength of light.

The quantum dots may have a relatively deep HOMO energy level, for example, the following HOMO energy level: greater than or equal to about 5.4 eV, within the range, for example, greater than or equal to about 5.5 eV, for example, greater than or equal to about 5.6 eV, for example, greater than or equal to about 5.7 eV, for example, greater than or equal to about 5.8 eV, for example, greater than or equal to about 5.9 eV, for example, greater than or equal to about 6.0 eV. Within the range, the HOMO energy level of the quantum dot layer 13 may be, for example, from about 5.4 eV to about 7.0 eV, for example, from about 5.4 eV to about 6.8 eV, for example, from about 5.4 eV to about 6.7 eV, for example, from about 5.4 eV to about 6.5 eV, for example, from about 5.4 eV to about 6.3 eV, for example, from about 5.4 eV to about 6.2 eV, for example, from about 5.4 eV to about 6.1 eV, within the range, for example, from about 5.5 eV to about 7.0 eV, for example, from about 5.5 eV to about 6.8 eV, for example, from about 5.5 eV to about 6.7 eV, for example, from about 5.5 eV to about 6.5 eV, for example, from about 5.5 eV to about 6.3 eV, for example, from about 5.5 eV to about 6.2 eV, for example, from about 5.5 eV to about 6.1 eV, for example, from about 5.5 eV to about 7.0 eV, for example, from about 5.6 eV to about 6.8 eV, for example, from about 5.6 eV to about 6.7 eV, for example, from about 5.6 eV to about 6.5 eV, for example, from about 5.6 eV to about 6.3 eV, for example, from about 5.6 eV to about 6.2 eV, for example, from about 5.6 eV to about 6.1 eV, within the range, for example, from about 5.7 eV to about 7.0 eV, for example, from about 5.7 eV to about 6.8 eV, for example, from about 5.7 eV to about 6.7 eV, for example, from about 5.7 eV to about 6.5 eV, for example, from about 5.7 eV to about 6.3 eV, for example, from about 5.7 eV to about 6.2 eV, for example, from about 5.7 eV to about 6.1 eV, within the range, for example, from about 5.8 eV to about 7.0 eV, for example, from about 5.8 eV to about 6.8 eV, for example, from about 5.8 eV to about 6.7 eV, for example, from about 5.8 eV to about 6.5 eV, for example, from about 5.8 eV to about 6.3 eV, for example, from about 5.8 eV to about 6.2 eV, for example, from about 5.8 eV to about 6.1 eV, within the range, for example, from about 6.0 eV to about 7.0 eV, for example, from about 6.0 eV to about 6.8 eV, for example from about 6.0 eV to about 6.7 eV, for example, from about 6.0 eV to about 6.5 eV, for example from about 6.0 eV to about 6.3 eV, for example, from about 6.0 eV to about 6.2 eV.

The quantum dots may have a relatively shallow LUMO energy level, for example, less than or equal to about 3.7 eV, within the range, for example, less than or equal to about 3.6 eV, for example, less than or equal to about 3.5 eV, for example, less than or equal to about 3.4 eV, for example, less than or equal to about 3.3 eV, for example, less than or equal to about 3.2 eV, for example, less than or equal to about 3.0 eV. Within the range, the LUMO energy level of the quantum dot layer 13 may be from about 2.5 eV to about 3.7 eV, from about 2.5 eV to about 3.6 eV, from about 2.5 eV to about 3.5 eV, from about 2.5 eV to about 3.4 eV, from about 2.5 eV to about 3.3 eV, from about 2.5 eV to about 3.2 eV, from about 2.5 eV to about 3.1 eV, from about 2.5 eV to about 3.0 eV, from about 2.8 eV to about 3.7 eV, from about 2.8 eV to about 3.6 eV, from about 2.8 eV to about 3.5 eV, from about 2.8 eV to about 3.4 eV, from about 2.8 eV to about 3.3 eV, from about 2.8 eV to about 3.2 eV, from about 3.0 eV to about 3.7 eV, from about 3.0 eV to about 3.6 eV, from about 3.0 eV to about 3.5 eV, or from about 3.0 eV to about 3.4 eV.

The quantum dots may have an energy bandgap of from about 1.7 eV to about 2.3 eV, or from about 2.4 eV to about 2.9 eV. Within the range, for example, the quantum dot layer 13 may have the following energy bandgap: from about 1.8 eV to about 2.2 eV, or from about 2.4 eV to about 2.8 eV, within the range, for example, from about 1.9 eV to about 2.1 eV, for example, from about 2.4 eV to about 2.7 eV.

For example, a first color quantum dot included in the first color quantum dot layer 203 and a second color quantum dot included in the second color quantum dot layer 204 are the semiconductor compounds made of the elements in the group IIB and the group VIA, and the semiconductor compounds may be binary compounds, ternary compounds or quaternary compounds. For example, materials of the first color quantum dot and the second color quantum dot may be at least one of CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, CdZnSeS, CdZnSeTe, CdZnSTe, CdHgSeS, CdHgSeTe, CdHgSTe, HgZnSeS, HgZnSeTe, and HgZnSTe. Generally, when a quantum dot is excited by a blue light source, the quantum dot will emit excitation fluorescence at a specific wavelength, and the emitted fluorescence spectrum is determined by the chemical composition and particle size of the quantum dot material. As the particle size of the quantum dot material increases, the fluorescence spectrum emitted by the materials with the same chemical composition is red-shifted from green light to red light. The quantum dot material that emits red light and the quantum dot material that emits green light may be quantum dot materials with the same chemical composition but different particle sizes, or quantum dot materials with different chemical compositions, that is, the first color quantum dot and the second color quantum dot may be made of the same material but have different particle sizes, or the first color quantum dot and the second color quantum dot may be made of different materials.

For example, the quantum dot is a nanometer-level semiconductor. By applying a certain electric field or light pressure to a nanometer-level semiconductor material, the nanometer-level semiconductor material will emit light of a specific frequency, and the frequency of the emitted light will change with the change of the size of the semiconductor, so the color of the light emitted by the quantum dot can be controlled by adjusting the size of the quantum dot.

For example, by controlling the shape, the structure, and the size of the quantum dot, electronic states such as the energy gap width of the quantum dot, the size of exciton binding energy, and the energy blue shift of exciton can be easily adjusted. As the size of the quantum dot decreases, the spectrum of the quantum dot appears blue shift. The smaller the size of the quantum dot, the more significant the blue shift phenomenon. For example, for a cadmium selenide quantum dot, when the size of the cadmium selenide quantum dot is reduced from 10 nm to 2 nm, the color of light emitted by the cadmium selenide quantum dot changes from red to blue, and when the size of the cadmium selenide quantum dot is greater than or equal to 2 nm and less than 5 nm, the cadmium selenide quantum dot emits blue light: when the size of the cadmium selenide quantum dot is greater than or equal to 5 nm and less than 8 nm, the cadmium selenide quantum dot emits green light; and when the size of the cadmium selenide quantum dot is greater than or equal to 8 nm and less than 10 nm, the cadmium selenide quantum dot emits red light.

For example, the unique properties of the quantum dot are based on its own quantum size effect. When the particle size enters the nanoscale, size confinement will cause size effect, quantum confinement effect, macroscopic quantum tunneling effect and surface effect, thereby deriving that the nanometer system has different low-dimensional physical properties from the microscopic system, so that the quantum dot has different physical and chemical properties from the microscopic system. For example, the quantum dot has unique photoluminescence and electroluminescent properties due to the quantum size effect and the electric confinement effect. Compared with organic fluorescent dyes, the quantum dot has excellent optical properties such as high quantum yield, high photochemical stability, not easy to photolysis, wide excitation, narrow emission, high color purity, and luminous color can be adjusted by controlling the size of the quantum dot. In this way, the quantum dot electroluminescent device including a quantum dot light-emitting layer has advantages such as high luminous efficiency, good stability, long life, high brightness, wide color gamut, and the like.

For example, in one example, the first color quantum dot included in the first color quantum dot layer, the second color quantum dot included in the second color quantum dot layer, and the third color quantum dot included in the third color quantum dot layer all include a quantum dot body and a ligand connected to the quantum dot body. The structure of the ligand is A-B-C type, A is a ligating group respectively connected to the quantum dot body of the first color quantum dot, the quantum dot body of the second color quantum dot and the quantum dot body of the third color quantum dot, and the ligating group may be —SH, —COOH, —NH₂ or multi-dentate ligand; B is a reactant after a photosensitive group is illuminated, and is configured to make the first color quantum dot, the second color quantum dot or the third color quantum dot undergo photocrosslinking, and the photosensitive group may be an alkenyl group, a carbonyl group, an epoxy group or a Boc-amino group; and C is —COOH, and is configured to react with developer.

For example, on the one hand, tetramethylammonium hydroxide (TMAH) as a weak alkaline developer reacts with a carboxyl group to form ionic ligand with good solubility; on the other hand, the tetramethylammonium hydroxide (TMAH) is a surfactant, one end of the TMAH is a hydroxyl group, which is a polar group, and the other end of the TMAH is tetramethylammonium, which is a quaternary ammonium group and is a non-polar group, which can well improve the solubility of the quantum dot in the developer to facilitate the elution of the quantum dot. It should be noted that the material of the developer may also be a series of polyalkyl quaternary ammonium salt such as tetraethylammonium hydroxide, tetrapropylammonium hydroxide, tetrabutylammonium hydroxide, cetyltrimethylammonium bromide (CTAB), or the like, and may also be a double quaternary ammonium salt (a kind of gemini surfactant) formed by connecting two single quaternary ammonium salt.

For example, the multidentate ligand is a ligand having two or more ligating atoms in one ligand, for example, diethylenetriamine (abbreviated as DEN) and ethylenediamine tetraacetic acid (abbreviated as EDTA).

For example, in another example, the first color quantum dot included in the first color quantum dot layer, the second color quantum dot included in the second color quantum dot layer, and the third color quantum dot included in the third color quantum dot layer all include a quantum dot body and a ligand connected to the quantum dot body. The structure of the ligand is a mixture of an A-B type ligand and an A-C type ligand, A is a ligating group respectively connected to the quantum dot body of the first color quantum dot, the quantum dot body of the second color quantum dot and the quantum dot body of the third color quantum dot, and the ligating group may be —SH, —COOH, —NH₂ or the multidentate ligand ligand; B is a reactant after a photosensitive group is illuminated, and is configured to make the first color quantum dot, the second color quantum dot or the third color quantum dot undergo photocrosslinking, C is —COOH, and is configured to react with developer; and the photosensitive group may be an alkenyl group, a carbonyl group, an epoxy group or a Boc-amino group.

For example, the A-B type ligand can achieve a photocuring property of the quantum dot, and the A-C type ligand can achieve a good elution property of the quantum dot.

For example, the first color quantum dot layer 203 and the second color quantum dot layer 204 may further include a thickening agent, a coupling agent, an accelerator, etc., and the content thereof may be adjusted as required.

For example, the thickening agent may be at least one of methyl vinyl MQ silicone resin, polymethacrylate, and polycyanoacrylate. The coupling agent is at least one of vinyltrimethoxysilane, vinyltriethoxysilane and vinyl-tris-(2-methoxyethoxy)silane. The accelerator is N,N-dimethylaniline, N,N-dimethyl-p-toluidine, or 2,4,6-tris(dimethylaminomethyl)phenol.

For example, the base substrate 201 includes a transparent insulating substrate such as a glass substrate, a flexible base substrate, or the like, and the material of the base substrate 201 may also be other suitable materials, which are not limited in the embodiments of the present disclosure.

It should be noted that although only two openings 2021 are illustrated in FIG. 3, the embodiments of the present disclosure are not limited thereto, and there may be more openings 2021, that is, there may be more sub-pixel regions 2022. Other layer structures may also be disposed between the base substrate 201 and the first color quantum dot layer 203 as well as the second color quantum dot layer 204, for example, organic functional layers and/or electrode structures, and a part of the layer structure is illustrated in FIG. 3 for simplicity.

For example, a quantum dot light-emitting diode in the quantum dot electroluminescent device usually includes a cathode, an anode, and a quantum dot light-emitting layer arranged between the cathode and the anode, and the quantum dot light-emitting diode may further includes an organic functional layer between the cathode and the quantum dot light-emitting layer, or between the anode and the quantum dot light-emitting layer.

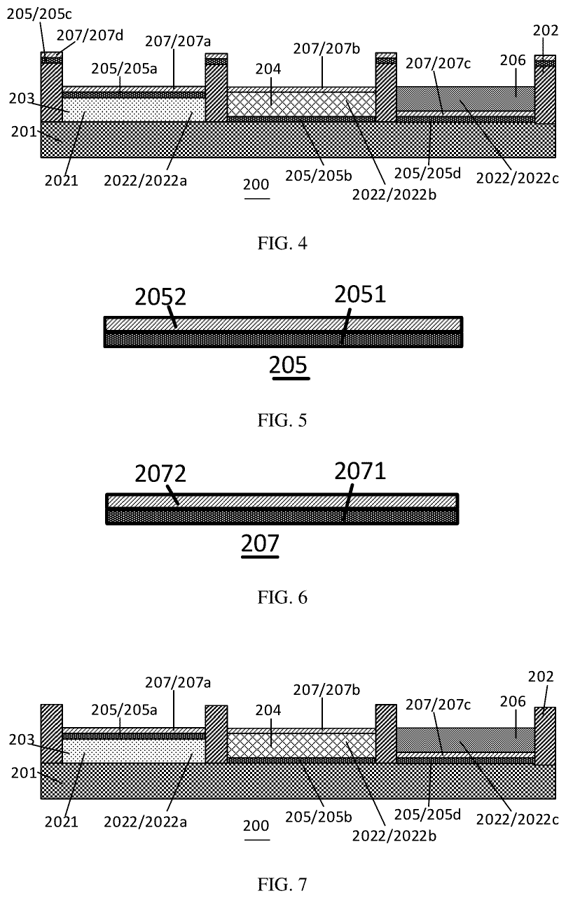

For example, FIG. 4 is a schematic diagram of a cross-sectional structure of another display substrate provided by at least one embodiment of the present disclosure. As illustrated in FIG. 4, in the display substrate 200, three sub-pixel regions 2022 are illustrated, the first color quantum dot layer 203 is disposed in the first sub-pixel region 2022a, the second color quantum dot layer 204 is disposed in the second sub-pixel region 2022b, and the third color quantum dot layer 206 is disposed in the third sub-pixel region 2022c. For example, the first color quantum dot layer 203 may include red quantum dots, the second color quantum dot layer 204 may include green quantum dots, and the third color quantum dot layer 206 may include blue quantum dots, so that the red light emitted from the first color quantum dot layer 203, the green light emitted from the second color quantum dot layer 204 and the blue light emitted from the third color quantum dot layer 206 can be mixed to form white light. Thus, the quantum dot electroluminescent device can have good display color. The materials of the red quantum dots, the green quantum dots, and the blue quantum dots are not particularly limited, and those skilled in the art can choose according to the above-mentioned common materials of the red quantum dots, the green quantum dots, and the blue quantum dots. The following takes the case where the first color quantum dot layer 203 is formed first, then the second color quantum dot layer 204 is formed, and the third color quantum dot layer 206 is finally formed as an example for illustration.

For example, as illustrated in FIG. 4, the first auxiliary layer 205 is formed on the entire surface, and the first auxiliary layer 205 at least includes a first portion 205a, a second portion 205b, a third portion 205c, and an eighth portion 205d spaced apart from each other. The first portion 205a is disposed on a side of the first color quantum dot layer 203 away from the base substrate 201, the second portion 205b is disposed on a side of the second color quantum dot layer 204 close to the base substrate 201, the third portion 205c is disposed on a side of the pixel definition layer 202 away from the base substrate 201, and the eighth portion 205d is disposed on a side of the third color quantum dot layer 206 close to the base substrate 201. Because the portion of the pixel definition layer 202 except the opening 2021 has a segment difference from the opening 2021, the first portion 205a, the second portion 205b, the third portion 205c and the eighth portion 205d are in a disconnected state during the forming process. For example, there is a height difference between the third portion 205c and the first portion 205a, between the third portion 205c and the second portion 205b, and between the third portion 205c and the eighth portion 205d in a direction perpendicular to the main surface of the base substrate 201. For example, the height difference between the third portion 205c and the first portion 205a, the height difference between the third portion 205c and the second portion 205b, and the height difference between the third portion 205c and the eighth portion 205d in the direction perpendicular to the main surface of the base substrate 201 are greater than the thickness of the third portion 205c in the direction perpendicular to the main surface of the base substrate 201. For example, the height difference between the third portion 205c and the first portion 205a in the direction perpendicular to the main surface of the base substrate 201 is greater than or equal to 4 times the thickness of the third portion 205c in the direction perpendicular to the main surface of the base substrate 201, and less than or equal to 6 times the thickness of the third portion 205c in the direction perpendicular to the main surface of the base substrate 201. The height difference between the third portion 205c and the second portion 205b in the direction perpendicular to the main surface of the base substrate 201 is greater than or equal to 8 times the thickness of the third portion 205c in the direction perpendicular to the main surface of the base substrate 201, and less than or equal to 11 times the thickness of the third portion 205c in the direction perpendicular to the main surface of the base substrate 201. The height difference between the third portion 205c and the eighth portion 205d in the direction perpendicular to the main surface of the base substrate 201 is greater than or equal to 8 times the thickness of the third portion 205c in the direction perpendicular to the main surface of the base substrate 201, and less than or equal to 11 times the thickness of the third portion 205c in the direction perpendicular to the main surface of the base substrate 201.

For example, as illustrated in FIG. 4, the display substrate 200 further includes a second auxiliary layer 207, and the second auxiliary layer 207 is at least disposed on the side of the second color quantum dot layer 204 away from the base substrate 201. In FIG. 4, a portion of the second auxiliary layer 207 is disposed on the side of the first auxiliary layer 205 corresponding to the first color quantum dot layer 203 away from the base substrate 201, and is disposed on the side of the second color quantum dot layer 204 away from the base substrate 201; and the other portion of the second auxiliary layer 207 is disposed on the side of the third color quantum dot layer 206 close to the base substrate 201, and is between the third color quantum dot layer 206 and the first auxiliary layer 205 corresponding to the third color quantum dot layer 206.

For example, in one example, the material of the first auxiliary layer 205 and the material of the second auxiliary layer 207 are the same, so that the types of materials used can be reduced, and the first auxiliary layer 205 and the second auxiliary layer 207 can also be formed by using the same equipment and the same process conditions, thereby saving equipment costs.

For example, in another example, the material of the first auxiliary layer 205 and the material of the second auxiliary layer 207 are different, so that the problem of color mixing can be avoided to the greatest extent according to the requirements of the process, so as to improve the color gamut of the electroluminescent device formed subsequently.

For example, as illustrated in FIG. 4, the second auxiliary layer 207 at least includes a fourth portion 207a, a fifth portion 207b, and a sixth portion 207c spaced apart from each other, and the fourth portion 207a is disposed on the side of the first portion 205a included in the first auxiliary layer 205 away from the base substrate 201, and is at least partially in contact with the first portion 205a, that is, in the first sub-pixel region 2022a, the first portion 205a of the first auxiliary layer 205 and the fourth portion 207a of the second auxiliary layer 207 are at least partially in contact with each other and surface bonded to each other. It should be noted that, in the case where there is no second color quantum dot material in the first sub-pixel region 2022a, the first portion 205a and the fourth portion 207a are in direct contact with each other and surface bonded to each other; and in the case where a part of the second color quantum dot materials is in the first sub-pixel region 2022a, the first portion 205a and the fourth portion 207a may be partially contacted with each other, but the residual second color quantum dot materials may be distributed in a point shape rather than in a whole plane. The fifth portion 207b is disposed on the side of the second color quantum dot layer 204 away from the base substrate 201, that is, in the second sub-pixel region 2022b, the second color quantum dot layer 204 is sandwiched between the second portion 205b of the first auxiliary layer 205 and the fifth portion 207b of the second auxiliary layer 207. The sixth portion 207c is disposed on the side of the third color quantum dot layer 206 close to the base substrate 201, that is, in the third sub-pixel region 2022c, the side of the third color quantum dot layer 206 close to the base substrate 201 has the eighth portion 205d of the first auxiliary layer 205 and the sixth portion 207c of the second auxiliary layer 207 laminated on each other, and the eighth portion 205d is on the side of the sixth portion 207c close to the base substrate 201.

For example, as illustrated in FIG. 4, the second auxiliary layer 207 further includes a seventh portion 207d spaced apart from the fourth portion 207a, the fifth portion 207b, and the sixth portion 207c, and the seventh portion 207d is disposed on the side of the third portion 205c away from the base substrate, and is at least partially in contact with the third portion 205c. It should be noted that, in the case where there is no second color quantum dot material in the pixel definition layer 202, the seventh portion 207d and the third portion 205c are in direct contact with each other and surface bonded to each other; and in the case where a part of the second color quantum dot material is in the pixel definition layer 202, the seventh portion 207d and third portion 205c may be partially contacted with each other. That is, the third portion 205c of the first auxiliary layer 205 and the seventh portion 207d of the second auxiliary layer 207 are laminated on all portions of the pixel definition layer 202 except the opening 202l.

It should be noted that when the formation order of the first color quantum dot layer 203, the second color quantum dot layer 204 and the third color quantum dot layer 206 changes, the structure of the first auxiliary layer 205 will also change.

For example, in the case where the second color quantum dot layer 204 is formed first, then the first color quantum dot layer 203 is formed, and the third color quantum dot layer 206 is finally formed, in the second sub-pixel region 2022b, the side of the second color quantum dot layer 204 away from the base substrate 201 is provided with the first auxiliary layer 205 and the second auxiliary layer 207 which are stacked in sequence: in the first sub-pixel region 2022a, the first color quantum dot layer 203 is sandwiched between the first auxiliary layer 205 and the second auxiliary layer 207, that is, the first auxiliary layer 205 is disposed on the side of the first color quantum dot layer 203 close to the base substrate 201, and the second auxiliary layer 207 is disposed on the side of the first color quantum dot layer 203 away from the substrate 201; and in the third sub-pixel region 2022c, the side of the third color quantum dot layer 206 close to the base substrate 201 is provided with the first auxiliary layer 205 and the second auxiliary layer 207 which are stacked in sequence.

For example, in the case where the third color quantum dot layer 206 is formed first, then the first color quantum dot layer 203 is formed, and the second color quantum dot layer 204 is finally formed, in the third sub-pixel region 2022c, the side of the third color quantum dot layer 206 away from the base substrate 201 is provided with the first auxiliary layer 205 and the second auxiliary layer 207 which are stacked in sequence: in the first sub-pixel region 2022a, the first color quantum dot layer 203 is sandwiched between the first auxiliary layer 205 and the second auxiliary layer 207, that is, the first auxiliary layer 205 is disposed on the side of the first color quantum dot layer 203 close to the base substrate 201, and the second auxiliary layer 207 is disposed on the side of the first color quantum dot layer 203 away from the substrate 201; and in the second sub-pixel region 2022b, the side of the second color quantum dot layer 204 close to the base substrate 201 is provided with the first auxiliary layer 205 and the second auxiliary layer 207 which are stacked in sequence.

For example, in one example, the material of the first auxiliary layer 205 and the material of the second auxiliary layer 207 include at least one of an electron-transporting type oxide and a hole-transporting type oxide, for example, the material of the first auxiliary layer 205 and the material of the second auxiliary layer 207 may both include the electron-transporting type oxide: the material of the first auxiliary layer 205 and the material of the second auxiliary layer 207 may also both include the hole-transporting type oxide; or, the material of the first auxiliary layer 205 includes the electron-transporting type oxide, and the material of the second auxiliary layer 207 includes the hole-transporting type oxide, which are not limited in the embodiments of the present disclosure.

For example, the material of the first auxiliary layer includes the electron-transporting type oxide, the material of the second auxiliary layer includes the hole-transporting type oxide, at least a part of the first auxiliary layer is in contact with the first color quantum dot layer, and at least a part of the second auxiliary layer is in contact with the third color quantum dot layer. For example, the first color quantum dot layer is a blue quantum dot layer, the second color quantum dot layer is one of a red quantum dot layer and a green quantum dot layer, and the third color quantum dot layer is the other one of the green quantum dot layer and the red quantum dot layer. Compared with the case where both the material of the first auxiliary layer and the material of the second auxiliary layer are the hole-transporting type oxide or the electron-transporting type oxide, in the case where the material of the first auxiliary layer is the electron-transporting type oxide, and the material of the second auxiliary layer is the hole-transporting type oxide, the electron-transporting effect and the hole-transporting effect are better. In the case where both the material of the first auxiliary layer and the material of the second auxiliary layer are hole-transporting type oxide, or both the material of the first auxiliary layer and the material of the second auxiliary layer are the electron-transporting type oxide, the laminated thickness of the first auxiliary layer and the second auxiliary layer is too thick, the effect of electron blocking or hole blocking may be too strong, thereby affecting the performance of the electroluminescent device formed finally.

For example, the material of the first auxiliary layer includes the electron-transporting type oxide, the material of the second auxiliary layer includes the hole-transporting type oxide, and the beneficial effects of that at least a part of the first auxiliary layer is in contact with the first color quantum dot layer, and at least a part of the second auxiliary layer is in contact with the third color quantum dot layer include: for the first sub-pixel manufactured previously, for example, a blue sub-pixel, only one layer of hole-transporting type oxide is deposited after the first color quantum dot layer is formed, while the second layer of the electron-transporting type oxide can be directly served as an electron-transporting layer, which does not make a hole-transporting type interface layer too thick to affect injecting holes into the first color quantum dot: for the second sub-pixel manufactured secondly, for example, a green sub-pixel, an interface layer of the second color quantum dot layer has the same functions as the first auxiliary layer and the second auxiliary layer on two sides of the interface layer; and for the third sub-pixel manufactured last, for example, a red sub-pixel, an electron-transporting type interface layer of the red sub-pixel has the same function as the electron-transporting type oxide below, there is only one layer of hole-transporting type interface layer, and the thickness of the second auxiliary layer will not prevent holes from injecting into the third color quantum dot layer.

In addition, considering the difference in energy levels of the red quantum dot, the green quantum dot and the blue quantum dot, the red sub-pixel and the green sub-pixel are generally multi-electron devices, while the blue sub-pixel is generally a multi-hole device. Therefore, the first sub-pixel manufactured first is a blue sub-pixel, the material of the first auxiliary layer includes the electron-transporting type oxide, the green sub-pixel and the red sub-pixel may be sub-pixels manufactured second or third respectively, and the material of the second auxiliary layer includes the hole-transporting type oxide, so that the electron-transporting type oxide in the blue sub-pixel can block holes, and the hole-transporting type oxide in the third sub-pixel can block electrons to balance carriers, and improve the injection efficiency of the carriers.

For example, in one example, the material of the first auxiliary layer 205 and the material of the second auxiliary layer 207 each include an electron-transporting type oxide such as zinc oxide, tin oxide, or the like, or both include a hole-transporting type oxide such as gallium nitride, aluminum nitride, molybdenum oxide, nickel oxide, zirconium oxide, vanadium oxide, or the like, or zinc oxide doped with magnesium, tin, gallium, indium, zirconium, hafnium, yttrium, lithium or aluminum, or tin oxide doped with magnesium, tin, gallium, indium, zirconium, hafnium, yttrium, lithium or aluminum, which are not limited in the embodiments of the present disclosure.

For example, in one example, the general formulas of the material of the first auxiliary layer 205 and the material of the second auxiliary layer 207 each include at least one of P [symbol] CF₂ [symbol] ₙM-A,

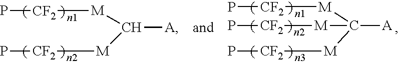

and A is at least one of —SH, —COOH and —NH₂; M is [symbol] CH₂ [symbol] _{X}, and X is less than or equal to 6; and P includes at least one of

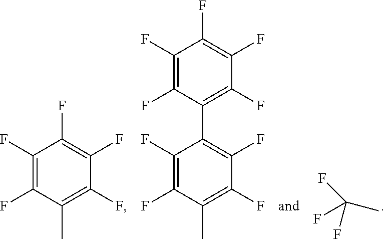

For example, in one example, the material of the first auxiliary layer 205 and the material of the second auxiliary layer 207 each include at least one of

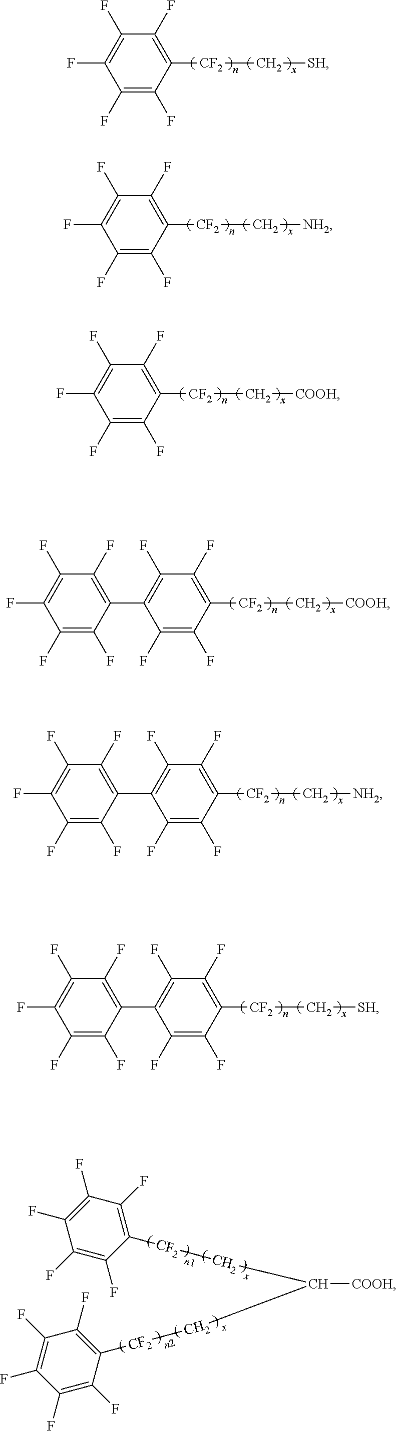

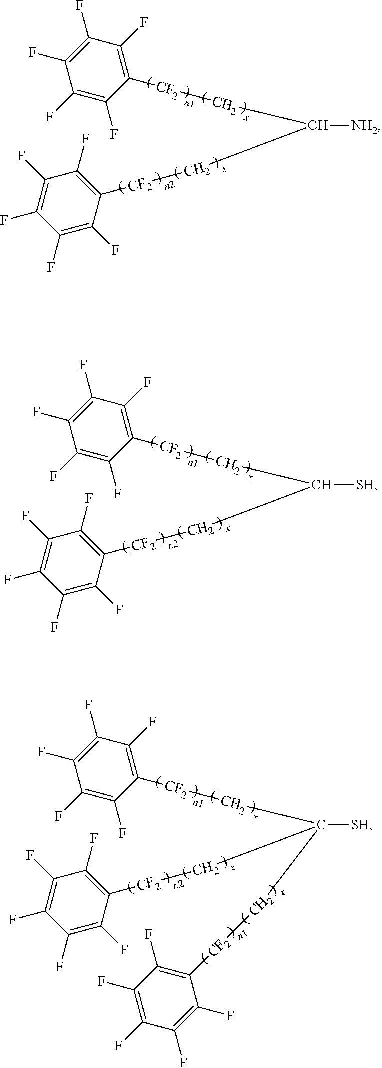

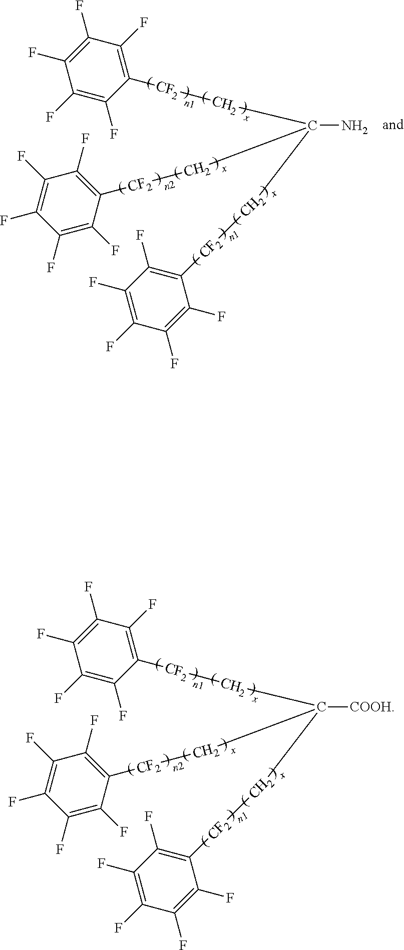

For example, in one example, the material of the first auxiliary layer 205 and the material of the second auxiliary layer 207 each include a first group, a second group and a third group, the first group includes —C(CF₃)₃, —CₙF(₂ₙ₊₁), or

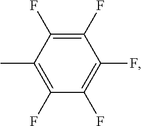

the second group includes a mercapto group, a carboxyl group or an amino group, and the third group includes at least one of an alkyl chain, an aromatic ring, an alkenyl group, an alkynyl group, an arylamine group, an epoxy group, and a ester group.

For example, FIG. 5 is a schematic diagram of a cross-sectional structure of a first auxiliary layer, in which a double-layer structure is laminated, provided by at least one embodiment of the present disclosure. As illustrated in FIG. 5, the first auxiliary layer 205 includes a first layer structure 2051 and a second layer structure 2052 which are stacked, the first layer structure 2051 is on the side of the second layer structure 2052 close to the base substrate 201, and the material of the first layer structure 2051 includes at least one of the electron-transporting type oxide and the hole-transporting type oxide.

For example, the material of the first layer structure includes at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, the general formula of the second layer structure 205 includes

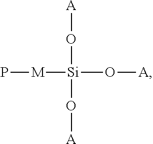

in which A is —(CH₂)nCH₃, and n is less than or equal to 4; M is —(CH₂)ₓ, and x is less than or equal to 6; and P includes at least one of

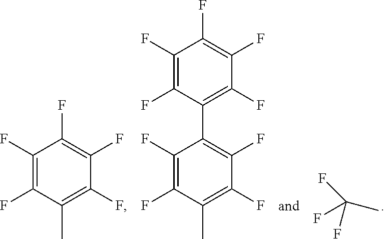

For example, the materials and the formation order of the first layer structure 2051 and the second layer structure 2052 cannot be changed, and the organic material in the second layer structure 2052 can reduce lattice defects and achieve the effect of insulation passivation.

For example, FIG. 6 is a schematic diagram of a cross-sectional structure of a second auxiliary layer with a double-layer structure, provided by at least one embodiment of the present disclosure. As illustrated in FIG. 6, the second auxiliary layer 207 includes a third layer structure 2071 and a fourth layer structure 2072 which are stacked, the third layer structure 2071 is on the side of the fourth layer structure 2072 close to the base substrate 201, and the material of the third layer structure 2071 includes at least one of the electron-transporting type oxide and the hole-transporting type oxide.

For example, the material of the third layer structure 2071 includes at least one selected from a group consisting of: zinc oxide, tin oxide, gallium nitride, aluminum nitride, molybdenum oxide, nickel oxide, zirconium oxide, vanadium oxide, zinc oxide doped with magnesium, tin, gallium, indium, zirconium, hafnium, yttrium, lithium or aluminum, and tin oxide doped with magnesium, tin, gallium, indium, zirconium, hafnium, yttrium, lithium or aluminum.

For example, the general formula of the fourth layer structure 2072 includes

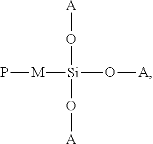

A is —(CH₂)nCH₃, and n is less than or equal to 4; M is —(CH₂)ₓ, and x is less than or equal to 6; and P includes at least one of

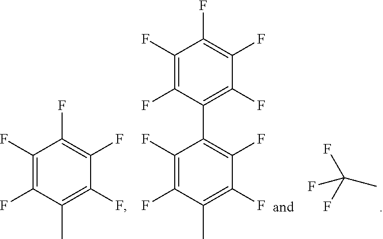

For example, the materials and formation order of the third layer structure 2071 and the fourth layer structure 2072 cannot be changed, and the organic material in the fourth layer structure 2072 can reduce lattice defects and achieve the effect of insulation passivation.

For example, in the case where the zinc oxide is formed by a sol-gel method, and then the zinc oxide manufactured by the sol-gel method is served as the material of the first auxiliary layer, many quantum dots are difficult to wash off. In the case where the zinc oxide formed by a sputtering method is served as the material of the first auxiliary layer, compared with the zinc oxide formed by the sol-gel method, the amount of quantum dots remaining on the zinc oxide formed by the sputtering method is less, and the structure of sputtered zinc oxide has the following characteristics: because the sputtered zinc oxide does not contain organic materials as raw materials, the surface roughness of the zinc oxide formed by the sputtering method is low and does not contain organic materials; in addition, the sputtered zinc oxide is non-nanoparticles, so the quantum dots have a weak binding force with a smooth surface of the sputtered zinc oxide, and the quantum dots applied on the zinc oxide are easily washed off without residue.

For example, FIG. 7 is a schematic diagram of a cross-sectional structure of still another display substrate provided by at least one embodiment of the present disclosure. The difference between the embodiment illustrated in FIG. 7 and the embodiment illustrated in FIG. 4 is that the first auxiliary layer 205 is patterned, and the first auxiliary layer 205 is not disposed on the surface of the pixel definition layer 202 away from the base substrate 201. As illustrated in FIG. 7, the first auxiliary layer 205 at least includes a first portion 205a, a second portion 205b, and an eighth portion 205d spaced apart from each other. The first portion 205a is disposed on the side of the first color quantum dot layer 203 away from the base substrate 201, the second portion 205b is disposed on the side of the second color quantum dot layer 204 close to the base substrate 201, and the eighth portion 205d is disposed on the side of the third color quantum dot layer 206 close to the base substrate 201. Because the portion of the pixel definition layer 202 except the opening 2021 has a segment difference from the opening 2021, the first portion 205a, the second portion 205b and the eighth portion 205d are in a disconnected state during the forming process.

For example, as illustrated in FIG. 7, the display substrate 200 further includes a second auxiliary layer 207, which is different from the embodiment illustrated in FIG. 4 in that the second auxiliary layer 207 is patterned, the second auxiliary layer 207 is not disposed on the surface of the pixel definition layer 202 away from the substrate 201, and the second auxiliary layer 207 is at least disposed on the side of the second color quantum dot layer 204 away from the substrate 201. In FIG. 7, a portion of the second auxiliary layer 207 is disposed on the side of the first auxiliary layer 205 corresponding to the first color quantum dot layer 203 away from the base substrate 201, and is disposed on the side of the second color quantum dot layer 204 away from the base substrate 201; and the other portion of the second auxiliary layer 207 is disposed on the side of the third color quantum dot layer 206 close to the base substrate 201, and is between the third color quantum dot layer 206 and the first auxiliary layer 205 corresponding to the third color quantum dot layer 206.

For example, in one example, the material of the first auxiliary layer 205 and the material of the second auxiliary layer 207 are the same, so that the types of the materials used can be reduced, and the first auxiliary layer 205 and the second auxiliary layer 207 can also be formed by using the same equipment and the same process conditions, thereby saving equipment costs.

For example, in another example, the material of the first auxiliary layer 205 and the material of the second auxiliary layer 207 are different, so that the problem of color mixing can be avoided to the greatest extent according to the needs of the process, so as to improve the color gamut of the electroluminescent device formed subsequently.

For example, as illustrated in FIG. 7, the second auxiliary layer 207 at least includes a fourth portion 207a, a fifth portion 207b, and a sixth portion 207c spaced apart from each other, and the fourth portion 207a is disposed on the side of the first portion 205a included in the first auxiliary layer 205 away from the base substrate 201, and is at least partially in contact with the first portion 205a, that is, in the first sub-pixel region 2022a, the first portion 205a of the first auxiliary layer 205 and the fourth portion 207a of the second auxiliary layer 207 are at least partially in contact with each other and surface bonded to each other. It should be noted that, in the case where there is no second color quantum dot material in the first sub-pixel region 2022a, the first portion 205a and the fourth portion 207a are in direct contact with each other and surface bonded to each other; and in the case where a part of the second color quantum dot materials in the first sub-pixel region 2022a, the first portion 205a and the fourth portion 207a may be partially contacted with each other, but the residual second color quantum dot materials may be distributed in a point shape rather than in a whole plane. The fifth portion 207b is disposed on the side of the second color quantum dot layer 204 away from the base substrate 201, that is, in the second sub-pixel region 2022b, the second color quantum dot layer 204 is sandwiched between the second portion 205b of the first auxiliary layer 205 and the fifth portion 207b of the second auxiliary layer 207. The sixth portion 207c is disposed on the side of the third color quantum dot layer 206 close to the base substrate 201, that is, in the third sub-pixel region 2022c, the side of the third color quantum dot layer 206 close to the base substrate 201 has the eighth portion 205d of the first auxiliary layer 205 and the sixth portion 207c of the second auxiliary layer 207 which are stacked, and the eighth portion 205d is on the side of the sixth portion 207c close to the base substrate 201.

It should be noted that when the formation order of the first color quantum dot layer 203, the second color quantum dot layer 204 and the third color quantum dot layer 206 changes, the structure of the first auxiliary layer 205 will also change.

For example, in the case where the second color quantum dot layer 204 is formed first, then the first color quantum dot layer 203 is formed, and the third color quantum dot layer 206 is finally formed, in the second sub-pixel region 2022b, the side of the second color quantum dot layer 204 away from the base substrate 201 is provided with the first auxiliary layer 205 and the second auxiliary layer 207 laminated in sequence: in the first sub-pixel region 2022a, the first color quantum dot layer 203 is sandwiched between the first auxiliary layer 205 and the second auxiliary layer 207, that is, the first auxiliary layer 205 is disposed on the side of the first color quantum dot layer 203 close to the base substrate 201, and the second auxiliary layer 207 is disposed on the side of the first color quantum dot layer 203 away from the substrate 201; and in the third sub-pixel region 2022c, the side of the third color quantum dot layer 206 close to the base substrate 201 is provided with the first auxiliary layer 205 and the second auxiliary layer 207 laminated in sequence.

For example, in the case where the third color quantum dot layer 206 is formed first, then the first color quantum dot layer 203 is formed, and the second color quantum dot layer 204 is finally formed, in the third sub-pixel region 2022c, the side of the third color quantum dot layer 206 away from the base substrate 201 is provided with the first auxiliary layer 205 and the second auxiliary layer 207 laminated in sequence: in the first sub-pixel region 2022a, the first color quantum dot layer 203 is sandwiched between the first auxiliary layer 205 and the second auxiliary layer 207, that is, the first auxiliary layer 205 is disposed on the side of the first color quantum dot layer 203 close to the base substrate 201, and the second auxiliary layer 207 is disposed on the side of the first color quantum dot layer 203 away from the substrate 201; and in the second sub-pixel region 2022b, the side of the second color quantum dot layer 204 close to the base substrate 201 is provided with the first auxiliary layer 205 and the second auxiliary layer 207 laminated in sequence.

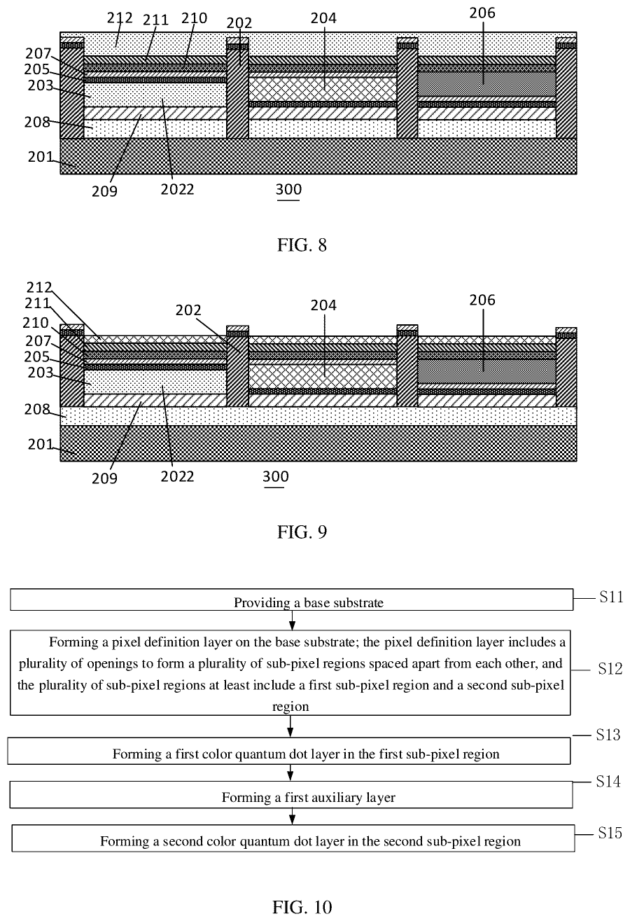

For example, FIG. 8 is a schematic diagram of a cross-sectional structure of an electroluminescent device provided by at least one embodiment of the present disclosure. As illustrated in FIG. 8, the electroluminescent device 300 includes the display substrate 200 according to any one of the above mentioned embodiments, and the electroluminescent device 300 further includes a first electrode 208 and a first functional layer 209 laminated on the base substrate 201. The first electrode 208 is disposed on a side of the first functional layer 209 close to the base substrate 201, the first functional layer 209 and the first electrode 208 are laminated in the plurality of sub-pixel regions 2022, and in the first sub-pixel region 2022a, the first functional layer 209 and the first electrode 208 which are stacked are between the first color quantum dot layer 203 and the base substrate 201: in the second sub-pixel region 2022b, the first functional layer 209 and the first electrode 208 which are stacked are between the second color quantum dot layer 204 and the base substrate 201; and in the third sub-pixel region 2022c, the first functional layer 209 and the first electrode 208 which are stacked are between the third color quantum dot layer 206 and the base substrate 201.

For example, as illustrated in FIG. 8, the electroluminescent device 300 further includes a second functional layer 210 and a third functional layer 211 disposed in a plurality of sub-pixel regions 2022 and on the side of the first color quantum dot layer 203, the second color quantum dot layer 204 and the third color quantum dot layer 206 away from the base substrate 201, and in different sub-pixel regions 2022, the second functional layer 210 and the third functional layer 211 which are stacked are spaced apart from each other. The entire surface of the second electrode 212 is disposed on a side of the third functional layer 211 away from the base substrate 201, and the third functional layer 211 is on a side of the second functional layer 210 away from the base substrate 201.

For example, in one example, the first functional layer 209 is an electron transporting layer, the second functional layer 210 is a hole transporting layer, and the third functional layer 211 is a hole injection layer.

For example, the material of the hole transporting layer includes any one of N,N′-bis(1-naphthyl)-N,N′-diphenyl-1,1′-diphenyl-4,4′-diamine (NPB), 4,4′,4″-tris(N-3-methylphenyl-N-phenylamino)triphenylamine (m-MTDATA), and 4,4-2-[N-(4-phenylcarbazole)-N-phenylamino]biphenyl (CPB), which are not limited thereto.

For example, the hole injection layer may be made of a metal oxide MeO, such as MoO₃, or a p-type doped MeO (a metal oxide)-TPD(N,N′10-bis(3-methylphenyl)-N,N′-diphenyl-1,1′-diphenyl-4,4′-diamine): F4TCNQ(N,N,N′,N′-tetramethoxyphenyl)-p-diaminodiphenyl: 2,3,5,6-tetrafluoro-7,7′,8,8′-tetracyanodimethyl-p-benzoquinone) or m-MTDATA: F4TCNQ (4,4′,4″-tri (N-3-methylphenyl-N-phenylamino)triphenylamine: 2,3,5,6-tetrafluoro-7,7′,8,8′-tetracyanodimethyl-p-benzoquinone), etc.

For example, in one example, the electron-transporting layer may include first inorganic nanoparticles or a first inorganic layer. The first inorganic nanoparticles may be, for example, oxide nanoparticles, and may be, for example, metal oxide nanoparticles.

For example, the first inorganic nanoparticles may be two-dimensional or three-dimensional nanoparticles having an average particle diameter as follows: less than or equal to about 10 nm, within the range, less than or equal to about 8 nm, less than or equal to about 7 nm, less than or equal to about 5 nm, less than or equal to about 4 nm, or less than or equal to about 3.5 nm, or within the range, from about 1 nm to about 10 nm, from about 1 nm to about 9 nm, from about 1 nm to about 8 nm, from about 1 nm to about 7 nm, from about 1 nm to about 5 nm, from about 1 nm to about 4 nm, or from about 1 nm to about 3.5 nm.

For example, the first inorganic nanoparticles may be metal oxide nanoparticles including at least one of the following: zinc (Zn), magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), hafnium (Hf), and barium (Ba).

As one example, the first inorganic nanoparticles may include metal oxide nanoparticles including zinc (Zn), and may include metal oxide nanoparticles represented by Znl-xQxO (0≤x<0.5). Here, Q is at least one metal other than Zn, such as magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), hafnium (Hf), silicon (Si), barium (Ba), or a combination thereof.

For example, Q may include magnesium (Mg).

For example, x may be within a range of 0.01≤x≤0.3, for example, 0.01≤x≤0.2.

For example, the material of the first inorganic layer is a metal oxide, and the metal oxide includes at least one of the following: zinc (Zn), magnesium (Mg), cobalt (Co), nickel (Ni), gallium (Ga), aluminum (Al), calcium (Ca), zirconium (Zr), tungsten (W), lithium (Li), titanium (Ti), tantalum (Ta), tin (Sn), hafnium (Hf), and barium (Ba).

For example, in one example, the material of the electron-transporting layer includes any one of 4,7-diphenyl-1,10-phenanthroline(BPhen), 1,3,5-tris(1-phenyl-1H-benzimidazol-2-yl)benzene(TPBI), and an n-type doped electron-transporting material, which are not limited thereto. The n-type doped electron-transporting material includes, for example, 2,9-dimethyl-4,7-biphenyl-1,10-phenanthroline(BCP): Li₂CO₃, 8-aluminum hydroxyquinoline (Alq₃): Mg, TPBI: Li, etc., but the embodiments of the present disclosure are not limited thereto.

For example, an electron injection layer may further be disposed between the first functional layer 209 and the base substrate 201, and the material of the electron injection layer includes any one of: lithium oxide (Li₂O), cesium oxide (Cs₂O), sodium oxide (Na₂O), lithium carbonate (Li₂CO₃), cesium carbonate (Cs₂CO₃), or sodium carbonate (Na₂CO₃), lithium fluoride (LiF), cesium fluoride (CsF), sodium fluoride (NaF), calcium fluoride (CaF₂), 8-aluminum hydroxyquinoline(Alq₃), 8-lithium hydroxyquinoline(Liq), 8-gallium hydroxyquinoline, bis[2-(2-hydroxyphenyl-1)-pyridine]beryllium, and 2-(4-diphenyl)-5-(4-tert-butylphenyl)-1,3,4-oxadiazole (PBD).

For example, the material of the first electrode may be a transparent conductive material, and the transparent conductive material includes any one of: indium tin oxide (ITO), indium zinc oxide (IZO), indium gallium oxide (IGO), gallium zinc oxide (GZO), zinc oxide (ZnO), indium oxide (In₂O₃), aluminum zinc oxide (AZO) and carbon nanotubes, etc.

For example, the material of the second electrode includes a single metal such as magnesium, aluminum, or lithium, or an alloy such as magnesium aluminum alloy (MgAl), lithium aluminum alloy (LiAl), or the like.

For example, the first electrode is an anode, and the second electrode is a cathode.

It should be noted that the materials and the structures of the above mentioned first electrode and the second electrode are only an example in the embodiments of the present disclosure, and the first electrode and the second electrode may also be made of other materials. According to the different materials of the first electrode and the second electrode, it can be divided into a single-sided light-emitting quantum dot device and a double-sided light-emitting quantum dot device. In the case where the material of one of the anode and cathode is an opaque or semi-transparent material, it is the single-sided light-emitting quantum dot device, and in the case where the materials of the anode and the cathode are both light-transmitting and/or semi-transparent materials, it is the double-sided light-emitting quantum dot device.

According to needs, the materials of the first electrode and the second electrode can be selected to be respectively applicable to the top emission type, the bottom emission type, and the double-sided emission type. The embodiments of the present disclosure do not limit the selection of the materials of the first electrode and the second electrode.

For example, in FIG. 8, the relevant features of the first color quantum dot layer 203, the second color quantum dot layer 204, the third color quantum dot layer 206, the first auxiliary layer 205 and the second auxiliary layer 207 can be referred to above. The related descriptions will not be repeated herein.

For example, FIG. 9 is a schematic diagram of a cross-sectional structure of another electroluminescent device provided by at least one embodiment of the present disclosure. As illustrated in FIG. 9, the electroluminescent device 300 includes the display substrate 200 according to any one of the above mentioned embodiments, and the electroluminescent device 300 further includes a first electrode 208 and a first functional layer 209 laminated on the base substrate 201. The entire surface of the first electrode 208 is disposed on the base substrate 201, and the first functional layer 209 is disposed on the side of the first electrode 208 away from the base substrate 201. The first functional layer 209 is disposed in a plurality of sub-pixel regions 2022, and in a first sub-pixel region 2022a, the first functional layer 209 is between a first color quantum dot layer 203 and the base substrate 201: in a second sub-pixel region 2022b, the first functional layer 209 is between a second color quantum dot layer 204 and the base substrate 201; and in a third sub-pixel region 2022c, the first functional layer 209 is between a third color quantum dot layer 206 and the base substrate 201.

For example, as illustrated in FIG. 9, the electroluminescent device 300 further includes a second functional layer 210, a third functional layer 211 and a second electrode 212, which are disposed in a plurality of sub-pixel regions 2022 and on the side of the first color quantum dot layer 203, the second color quantum dot layer 204 and the third color quantum dot layer 206 away from the base substrate 201. The third functional layer 211 is on the side of the second functional layer 210 away from the base substrate 201, and the second electrode 212 is on the side of the third functional layer 211 away from the base substrate 201. That is, the first electrode 208 is formed on the whole surface, and the second electrodes 212 are spaced apart from each other in different sub-pixel regions 2022, so that the first color quantum dot layer 203 in the first sub-pixel region 2022a can emit light of a first color, the second color quantum dot layer 204 in the second sub-pixel region 2022b can emit light of a second color, and the third color quantum dot layer 206 in the third sub-pixel region 2022c can emit light of a third color; and the light of the first color, the light of the second color and the light of the third color have different colors, so that the purity of the light emitted from each of the sub-pixel regions 2022 is higher.

For example, in FIG. 9, the relevant features of the first color quantum dot layer 203, the second color quantum dot layer 204, the third color quantum dot layer 206, the first auxiliary layer 205 and the second auxiliary layer 207 can refer to the related descriptions mentioned above, and the relevant descriptions will not be repeated herein.

For example, in one example, the first functional layer 209 is an electron transporting layer, the second functional layer 210 is a hole transporting layer, and the third functional layer 211 is a hole injection layer. The materials of the electron transporting layer, the hole transporting layer, the hole injection layer, the first electrode and the second electrode are not particularly limited, which may refer to the relevant descriptions in FIG. 8 mentioned above, and those skilled in the art can choose according to the common materials of the above structures of the quantum dot electroluminescent device.

At least one embodiment of the present disclosure further provides a manufacturing method of an electroluminescent device, and the manufacturing method includes: providing a base substrate; forming a pixel definition layer on the base substrate, in which the pixel definition layer includes a plurality of openings to form a plurality of sub-pixel regions spaced apart from each other, and the plurality of sub-pixel regions at least include a first sub-pixel region and a second sub-pixel region; forming a first color quantum dot layer in the first sub-pixel region; and forming a second color quantum dot layer in the second sub-pixel region. The manufacturing method further includes: forming a first auxiliary layer after forming the first color quantum dot layer and before forming the second color quantum dot layer, in which the first auxiliary layer at least includes a first portion and a second portion spaced apart from each other, the first portion is disposed on a side of the first color quantum dot layer away from the base substrate, and the second portion is disposed on a side of the second color quantum dot layer close to the base substrate.

For example, FIG. 10 is a flowchart of a manufacturing process of an electroluminescent device provided by at least one embodiment of the present disclosure. As illustrated in FIG. 10, the manufacturing method includes the following steps.

S11: providing a base substrate.

For example, the base substrate includes a transparent insulating substrate such as a glass substrate, a flexible base substrate, or the like, and the material of the base substrate may also be other suitable materials, which are not limited in the embodiments of the present disclosure.

S12: forming a pixel definition layer on the base substrate; the pixel definition layer includes a plurality of openings to form a plurality of sub-pixel regions spaced apart from each other, and the plurality of sub-pixel regions at least include a first sub-pixel region and a second sub-pixel region.

For example, the process of forming the pixel definition layer includes: depositing the material of the pixel definition layer on the base substrate, then applying a photoresist material on the material of the pixel definition layer, exposing and developing the photoresist material by using a mask to form a photoresist pattern, and then using the photoresist pattern as a mask to etch the material of the pixel definition layer to form the pixel definition layer: the etched portion of the material of the pixel definition layer forms a plurality of openings, and a plurality of sub-pixel regions are formed at positions corresponding to the plurality of openings, and the plurality of sub-pixel regions are spaced apart from each other, so that the plurality of sub-pixel regions at least include a first sub-pixel region and a second sub-pixel region spaced apart from each other.

S13: forming a first color quantum dot layer in the first sub-pixel region.

For example, forming the first color quantum dot layer in the first sub-pixel region may include: applying the material of the first color quantum dot layer in the plurality of sub-pixel regions to form a first color quantum dot film, and then performing a patterning process on the first color quantum dot film to form the first color quantum dot layer.

For example, performing the patterning process on the first color quantum dot film includes: using a mask to block a non-exposed region of the first color quantum dot film, for example, to block the second sub-pixel region and the third sub-pixel region; exposing a region to be exposed (the first sub-pixel region) to cross-link the first color quantum dot material in the first sub-pixel region, and performing a developing process; and removing the second color quantum dot material in the second sub-pixel region and the third sub-pixel region, thereby forming a patterned first color quantum dot layer.

For example, the first color quantum dot layer includes the material of the first color quantum dot, and the thickening agent, the coupling agent and the accelerator included in the first color quantum dot layer can refer to the relevant descriptions in the above embodiments, which will not be repeated herein.

S14: forming a first auxiliary layer.

For example, the first auxiliary layer has a characteristic of electron transmission, and the connection force between the first auxiliary layer and an uncrosslinked quantum dot material on it is weak, which makes the uncrosslinked quantum dot material easier to be washed off, thereby preventing the second color quantum dot material formed later from remaining on the first color quantum dot layer, thereby avoiding the problem of color mixing to improve the color gamut of the electroluminescent device.

For example, the structure and the material of the first auxiliary layer may refer to the relevant descriptions mentioned above, which will not be repeated herein.

S15: forming a second color quantum dot layer in the second sub-pixel region.

For example, forming the second color quantum dot layer in the second sub-pixel region may include: applying the material of the second color quantum dot layer in the plurality of sub-pixel regions to form a second color quantum dot film, and then performing a patterning process on the second color quantum dot film to form the second color quantum dot layer.

For example, performing the patterning process on the second color quantum dot film includes: using a mask to block a non-exposed region of the second color quantum dot film, for example, to block the first sub-pixel region and the third sub-pixel region; exposing a region to be exposed (the second sub-pixel region) to cross-link the second color quantum dot material in the second sub-pixel region, and performing a developing process; and removing the second color quantum dot material in the first sub-pixel region and the third sub-pixel region, thereby forming a patterned second color quantum dot layer.

For example, the second color quantum dot layer includes the material of the second color quantum dot, and the thickening agent, the coupling agent and the accelerator included in the second color quantum dot layer can refer to the relevant descriptions in the above embodiments, which will not be repeated herein.

For example, in one example, before forming the first color quantum dot layer, the manufacturing method further includes forming a first functional layer on the base substrate, and in the second sub-pixel region and the third sub-pixel region, the first functional layer and the first auxiliary layer are attached to each other. That is, the first functional layer is formed first, then the first color quantum dot layer is formed, then the first auxiliary layer is formed, and then the second color quantum dot layer and the third color quantum dot layer are formed.

For example, the first functional layer is the electron transporting layer, and the electron transporting layer can transport electrons. The material of the electron transporting layer may refer to the relevant descriptions in the above embodiments, which will not be repeated herein.

For example, in one example, the materials of the first auxiliary layer and the first functional layer are the same, for example, the materials of the first auxiliary layer and the first functional layer are both zinc oxide, and in the direction perpendicular to the main surface of the base substrate, the thickness of the first functional layer is 4 times to 5 times the thickness of the first auxiliary layer, for example, the thickness of the first functional layer is 4 times, 4.2 times, 4.4 times, 4.6 times, 4.8 times or 5 times the thickness of the first auxiliary layer.

For example, in one example, the thickness of the first color quantum dot layer is 4 times to 5 times the thickness of the first auxiliary layer, for example, the thickness of the first color quantum dot layer is 4 times, 4.2 times, 4.4 times, 4.6 times, 4.8 times or 5 times the thickness of the first auxiliary layer.

For example, in one example, the material of the first auxiliary layer includes at least one of an electron-transporting type oxide and a hole-transporting type oxide, and the first auxiliary layer is formed by a method of magnetron sputtering.

For example, the material of the first auxiliary layer includes an electron-transporting type oxide such as zinc oxide, tin oxide, or the like, or includes a hole-transporting type oxide such as gallium nitride, aluminum nitride, molybdenum oxide, nickel oxide, zirconium oxide, vanadium oxide, or the like, or zinc oxide doped with magnesium, tin, gallium, indium, zirconium, hafnium, yttrium, lithium or aluminum, or tin oxide doped with magnesium, tin, gallium, indium, zirconium, hafnium, yttrium, lithium or aluminum, which are not limited in the embodiments of the present disclosure.

For example, after the developing process, the force between the unexposed second color quantum dot and the first auxiliary layer (for example, sputtered zinc oxide) is small, and the second color quantum dot has less residue on the sputtered zinc oxide, so that the second color quantum dot has less residue in the first sub-pixel region.

For example, the first color quantum dot layer includes first color quantum dots, and forming the first auxiliary layer includes placing the base substrate formed with the first color quantum dot layer in a first solution for soaking, for example, the soaking time is 5 minutes to 30 minutes, and the first solution includes a first group containing a perfluoro terminal and a second group that can coordinate with the terminal of the first color quantum dot.

For example, in one example, the first group includes —C(CF₃)₃, —CₙF(₂ₙ₊₁), or

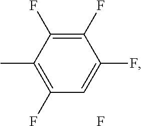

and the second group includes a mercapto group, a carboxyl group or an amino group.

For example, in one example, the first solution further includes a third group connected to the first group and the second group, and the third group includes an electron-absorbing group or an alkyl chain. For example, the electron-absorbing group is a group that reduces the electron cloud density on the benzene ring when a substituent replaces the hydrogen on the benzene ring: conversely, a group that increases the electron cloud density on the benzene ring is called an electron-donating group. Whether a group is an electron-absorbing group or an electron-donating group depends on the sum of its inductive effect, conjugation effect, and hyperconjugation effect on the benzene ring. The selection of the electron-absorbing group can reduce the transmission of electrons to a certain extent, prevent leakage, and facilitate the balance of carriers. In the case where the second group is a photosensitive group containing double bond, triple bond, epoxy, ester bond, etc., the ligand undertakes the photosensitive function of the quantum dot.

For example, in one example, the electron-absorbing group includes at least one of an aromatic ring, an alkenyl group, an alkynyl group, an arylamine group, an epoxy group, and an ester group.

For example, in one example, the general formula of the material of the first auxiliary layer includes at least one of P [symbol] CF₂ [symbol] M-A,

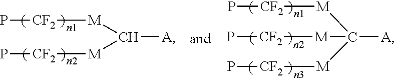

and A is at least one of —SH, —COOH and —NH₂; M is [symbol] CH₂ [symbol] _{X}, and X is less than or equal to 6; and P includes at least one of

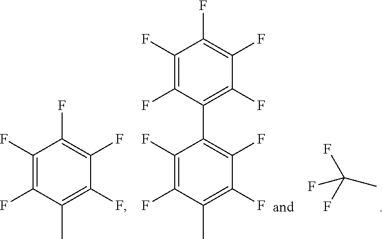

For example, in one example, the material of the first auxiliary layer includes at least one of

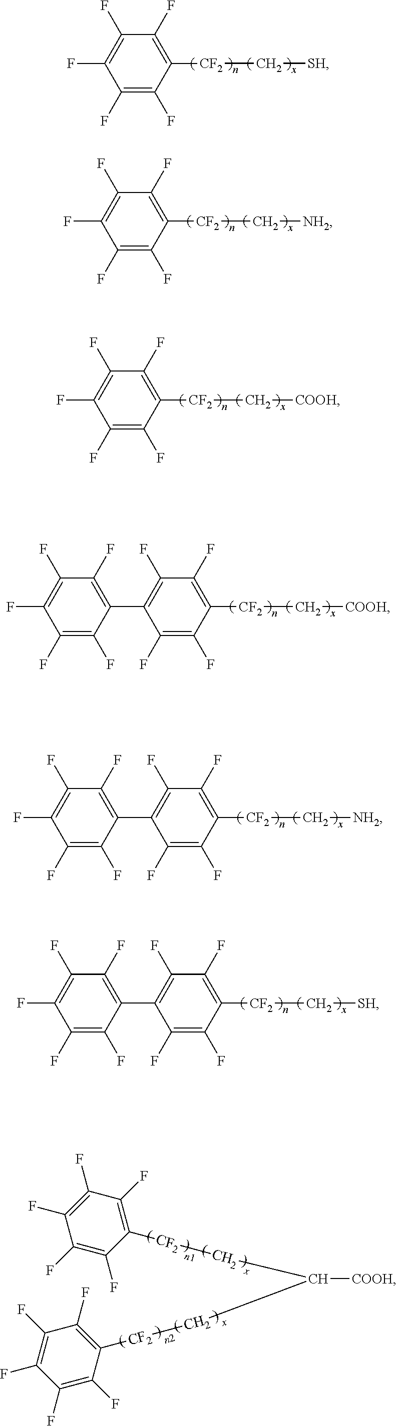

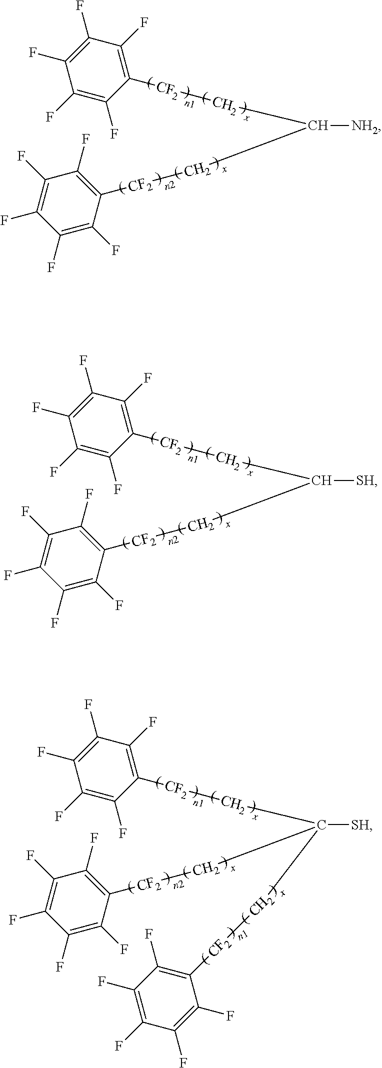

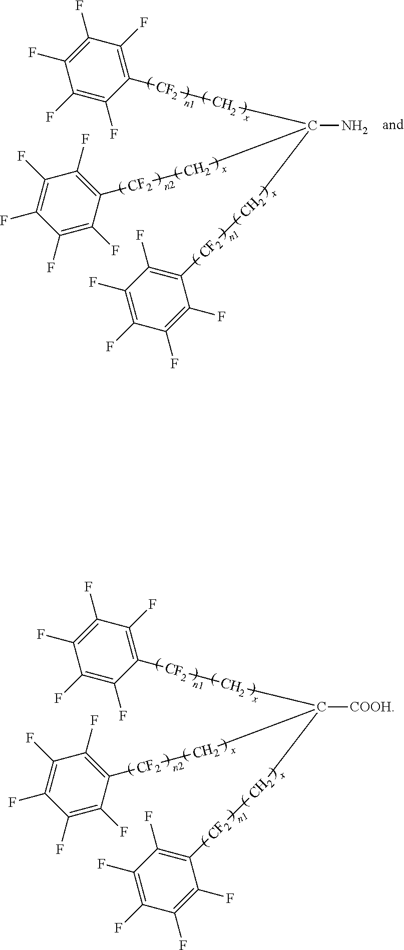

For example, in one example, forming the first auxiliary layer includes forming a first layer structure and a second layer structure which are stacked, the first layer structure is on a side of the second layer structure close to the base substrate, and forming the first layer structure includes applying at least one of the electron-transporting type oxide and the hole-transporting type oxide on the base substrate by the method of magnetron sputtering; and forming the second layer structure includes placing the base substrate formed with the first layer structure in a solution of a silane coupling agent for soaking, for example, the soaking time is 5 minutes to 30 minutes, and the solution of the silane coupling agent includes a first group containing a perfluoro terminal. The first group includes at least one of

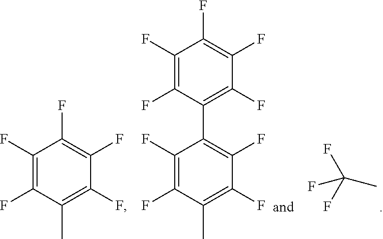

For example, the material of the first layer structure includes at least one of the electron-transporting type oxide and the hole-transporting type oxide. For example, the material of the first layer structure includes at least one selected from a group consisting of: the electron-transporting type oxide such as zinc oxide, tin oxide, etc., or the hole-transporting type oxide such as gallium nitride, aluminum nitride, molybdenum oxide, nickel oxide, zirconium oxide, vanadium oxide, etc., or zinc oxide doped with magnesium, tin, gallium, indium, zirconium, hafnium, yttrium, lithium or aluminum, or tin oxide doped with magnesium, tin, gallium, indium, zirconium, hafnium, yttrium, lithium or aluminum, and the embodiments of the present disclosure do not limit to this.

For example, the general formula of the material of the second layer structure includes

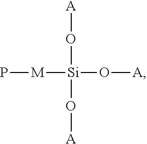

A is —(CH₂)nCH₃, and n is less than or equal to 4; M is —(CH₂)x, and x is less than or equal to 6; and P includes at least one of

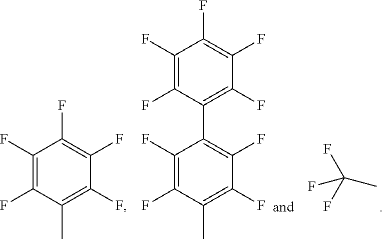

For example, in one example, a second auxiliary layer is at least formed on a side of the second color quantum dot layer away from the base substrate; and a third color quantum dot layer is formed on a side of the second auxiliary layer away from the base substrate and in the third sub-pixel region. The material of the first auxiliary layer is different from or the same as the material of the second auxiliary layer.

For example, the structure of the second auxiliary layer may be referred to the relevant descriptions mentioned above, which will not be repeated herein.

For example, in one example, the material of the second auxiliary layer includes at least one of the electron-transporting type oxide and the hole-transporting type oxide, and the second auxiliary layer is formed by the method of magnetron sputtering.

For example, the material of the second auxiliary layer includes an electron-transporting type material such as zinc oxide, tin oxide, or the like, or includes a hole-transporting type material such as gallium nitride, aluminum nitride, molybdenum oxide, nickel oxide, zirconium oxide, vanadium oxide, or the like, or zinc oxide doped with magnesium, tin, gallium, indium, zirconium, hafnium, yttrium, lithium or aluminum, or tin oxide doped with magnesium, tin, gallium, indium, zirconium, hafnium, yttrium, lithium or aluminum, which are not limited in the embodiments of the present disclosure.

For example, the second color quantum dot layer includes second color quantum dots, and forming the second auxiliary layer includes placing the base substrate formed with the second color quantum dot layer in a second solution for soaking, and the second solution includes a third group containing a perfluoro terminal and a fourth group that can coordinate with the terminal of the second color quantum dot.

For example, in one example, the third group includes —C(CF₃)₃, —CₙF(₂ₙ₊₁), or

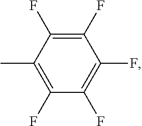

and the fourth group includes a mercapto group, a carboxyl group or an amino group.

For example, in one example, the second solution further includes a fifth group connected to the third group and the fourth group, and the fifth group includes an electron-absorbing group or an alkyl chain. For example, the general formula of the material of the second auxiliary layer formed by the second solution includes at least one of P [symbol] CF₂ [symbol] ₙM-A

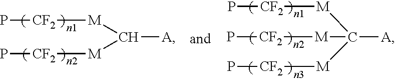

and A is at least one of —SH, —COOH and —NH₂; M is [symbol] CH₂ [symbol] ₓ, and X is less than or equal to 6; and P includes at least one of

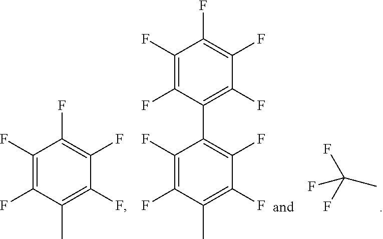

For example, in one example, forming the second auxiliary layer includes forming a third layer structure and a fourth layer structure which are stacked, the third layer structure is on a side of the fourth layer structure close to the base substrate, and forming the third layer structure includes applying at least one of the electron-transporting type oxide and the hole-transporting type oxide on the base substrate by the method of magnetron sputtering.

For example, forming the fourth layer structure includes placing the base substrate formed with the third layer structure in a solution of a silane coupling agent for soaking, and the solution of the silane coupling agent includes a third group containing a perfluoro terminal. For example, the third group includes at least one of

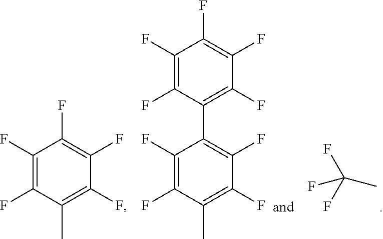

For example, in one example, the material of the third layer structure includes an electron-transporting type oxide such as zinc oxide, tin oxide, or the like, or includes a hole-transporting type oxide such as gallium nitride, aluminum nitride, molybdenum oxide, nickel oxide, zirconium oxide, vanadium oxide, or the like, or zinc oxide doped with magnesium, tin, gallium, indium, zirconium, hafnium, yttrium, lithium or aluminum, or tin oxide doped with magnesium, tin, gallium, indium, zirconium, hafnium, yttrium, lithium or aluminum.

For example, the material of the first auxiliary layer and the material of the second auxiliary layer are different, the material of the first auxiliary layer includes the electron-transporting type oxide, and the material of the second auxiliary layer includes the hole-transporting type oxide.

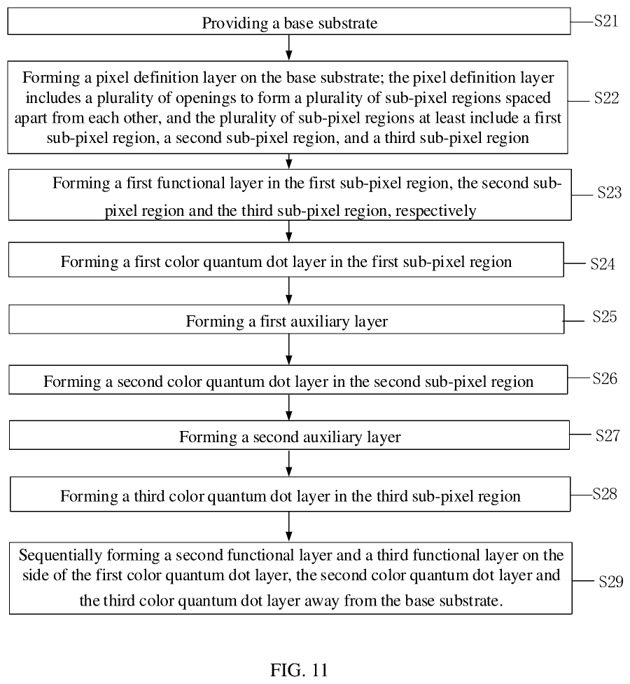

For example, FIG. 11 is a flowchart of a manufacturing process of another electroluminescent device provided by at least one embodiment of the present disclosure. As illustrated in FIG. 11, the manufacturing method includes the following steps.

S21: providing a base substrate.

For example, the material of the base substrate may refer to the relevant descriptions mentioned above, which are not limited in the embodiments of the present disclosure.

S22: forming a pixel definition layer on the base substrate; the pixel definition layer includes a plurality of openings to form a plurality of sub-pixel regions spaced apart from each other, and the plurality of sub-pixel regions at least include a first sub-pixel region, a second sub-pixel region, and a third sub-pixel region.

For example, the process of forming the pixel definition layer may be referred to the above descriptions of FIG. 9, which will not be repeated herein.

S23: forming a first functional layer in the first sub-pixel region, the second sub-pixel region and the third sub-pixel region, respectively.

For example, the first functional layer is an electron transporting layer. For example, the electron transporting layer may be made of a metal oxide, specifically, the material constituting the electron transporting layer may include at least one of zinc oxide, nickel oxide and titanium oxide. For example, the material of the electron transporting layer includes any one of 4,7-diphenyl-1,10-phenanthroline(BPhen), 1,3,5-tris(1-phenyl-1H-benzimidazol-2-yl)benzene(TPBI), and an n-type doped electron-transporting material, which are not limited in the embodiments of the present disclosure. The n-type doped electron-transporting material includes, for example, 2,9-dimethyl-4,7-biphenyl-1,10-phenanthroline(BCP): Li₂CO₃, 8-aluminum hydroxyquinoline (Alq₃): Mg, TPBI: Li, etc., but the embodiments of the present disclosure are not limited thereto.

For example, the first functional layer may be formed by the method of spin coating and annealing, or the first functional layer may be formed on the base substrate by the method of evaporation.

It should be noted that, before forming the first functional layer, an electron injection layer may also be formed on the base substrate, and the material of the electron injection layer may refer to the relevant descriptions mentioned above, which will not be repeated herein.

S24: forming a first color quantum dot layer in the first sub-pixel region.

For example, forming the first color quantum dot layer in the first sub-pixel region may include: applying the material of the first color quantum dot layer in the plurality of sub-pixel regions to form a first color quantum dot film, and then performing a patterning process on the first color quantum dot film to form the first color quantum dot layer.

For example, performing the patterning process on the first color quantum dot film includes: using a mask to block a non-exposed region of the first color quantum dot film, for example, to block the second sub-pixel region and the third sub-pixel region; exposing a region to be exposed (the first sub-pixel region) to cross-link the first color quantum dot material in the first sub-pixel region, and performing a developing process; and removing the second color quantum dot material in the second sub-pixel region and the third sub-pixel region, thereby forming a patterned first color quantum dot layer.

For example, the first color quantum dot layer includes the material of the first color quantum dot, and the thickening agent, the coupling agent and the accelerator included in the first color quantum dot layer can refer to the relevant descriptions in the above embodiments, which will not be repeated herein.

For example, a second color quantum dot layer and a third color quantum dot layer can be respectively formed in the second sub-pixel region and the third sub-pixel region subsequently.

S25: forming a first auxiliary layer.

For example, the first auxiliary layer has a characteristic of electron transmission, and the connection force between the first auxiliary layer and a uncrosslinked quantum dot material on it is weak, which makes the uncrosslinked quantum dot material easier to be washed off, thereby preventing the second color quantum dot material formed later from remaining on the first color quantum dot layer, thereby avoiding the problem of color mixing to improve the color gamut of the electroluminescent device.

For example, the first auxiliary layer is formed by a whole layer, the first auxiliary layer is formed in the first sub-pixel region, the second sub-pixel region and the third sub-pixel region, and the first auxiliary layer is formed on a side of the pixel definition layer away from the base substrate.

For example, the structure and the material of the first auxiliary layer may be referred to the relevant descriptions mentioned above, which will not be repeated herein.

S26: forming a second color quantum dot layer in the second sub-pixel region.

For example, forming the second color quantum dot layer in the second sub-pixel region may include: applying the material of the second color quantum dot layer in the plurality of sub-pixel regions to form a second color quantum dot film, and then performing a patterning process on the second color quantum dot film to form the second color quantum dot layer.

For example, performing the patterning process on the second color quantum dot film includes: using a mask to block a non-exposed region of the second color quantum dot film, for example, to block the first sub-pixel region and the third sub-pixel region; exposing a region to be exposed (the second sub-pixel region) to cross-link the second color quantum dot material in the second sub-pixel region, and performing a developing process; and removing the second color quantum dot material in the first sub-pixel region and the third sub-pixel region, thereby forming a patterned second color quantum dot layer.

For example, the second color quantum dot layer includes the material of the second color quantum dot, and the thickening agent, the coupling agent and the accelerator included in the second color quantum dot layer can refer to the relevant descriptions in the above embodiments, which will not be repeated herein.

S27: forming a second auxiliary layer.

For example, the connection force between the second auxiliary layer and the uncrosslinked quantum dot material on it is weak, which makes the uncrosslinked quantum dot material easier to be washed off, thereby preventing the third color quantum dot material formed later from remaining on the second color quantum dot layer and the first color quantum dot layer, thereby avoiding the problem of color mixing to improve the color gamut of the electroluminescent device.

For example, the second auxiliary layer is formed on a whole layer, the second auxiliary layer is formed in the first sub-pixel region, the second sub-pixel region and the third sub-pixel region, and is formed on the side of the pixel definition layer away from the base substrate. That is, the first auxiliary layer and the second auxiliary layer are sequentially laminated on the side of the pixel definition layer away from the base substrate.

For example, the structure and the material of the second auxiliary layer may be referred to the relevant descriptions mentioned above, which will not be repeated herein.

S28: forming a third color quantum dot layer in the third sub-pixel region.

For example, forming the third color quantum dot layer in the third sub-pixel region may include: applying the material of the third color quantum dot layer in the plurality of sub-pixel regions to form a third color quantum dot film, and then performing a patterning process on the third color quantum dot film to form the third color quantum dot layer.

For example, performing the patterning process on the third color quantum dot film includes: using a mask to block a non-exposed region of the third color quantum dot film, for example, to block the first sub-pixel region and the second sub-pixel region; exposing a region to be exposed (the third sub-pixel region) to cross-link the third color quantum dot material in the third sub-pixel region, and performing a developing process; and removing the third color quantum dot material in the first sub-pixel region and the second sub-pixel region, thereby forming a patterned third color quantum dot layer.

For example, the third color quantum dot layer includes the material of the third color quantum dot, and the thickening agent, the coupling agent and the accelerator included in the third color quantum dot layer can refer to the relevant descriptions in the above embodiments, which will not be repeated herein.

S29: sequentially forming a second functional layer and a third functional layer on the side of the first color quantum dot layer, the second color quantum dot layer and the third color quantum dot layer away from the base substrate.

For example, the method of forming the second functional layer and the third functional layer includes directly forming by the method of vapor deposition.

For example, in one example, the second functional layer is a hole transporting layer, and the third functional layer is a hole injection layer. The material of the second functional layer and the material of the third functional layer may be referred to the relevant descriptions mentionded above, which will not be repeated herein.

For example, before forming the pixel definition layer on the base substrate, a first electrode may be formed on the base substrate, and the first electrode may be formed on the entire surface.

For example, the material of the first electrode includes a transparent conductive metal oxide or a conductive polymer, and the conductive metal oxide may include any one of: indium tin oxide (ITO), indium zinc oxide (IZO), indium gallium oxide (IGO), gallium zinc oxide (GZO), zinc oxide (ZnO), indium oxide (In₂O₃), aluminum zinc oxide (AZO) and carbon nanotubes, etc.

For example, after the second functional layer and the third functional layer are formed, a second electrode may further be formed on the side of the third functional layer away from the base substrate, and the material of the second electrode includes a conductive metal or a conductive metal oxide. For example, the material of the second electrode includes a single metal such as magnesium, aluminum, or lithium, or an alloy such as magnesium aluminum alloy (MgAl), lithium aluminum alloy (LiAl), or the like.

For example, the first electrode is an anode, and the second electrode is a cathode.

For example, in another example, the first electrode may also be formed in the first sub-pixel region, the second sub-pixel region and the third sub-pixel region respectively, and the second electrode may be formed on the entire surface.

For example, the structures of the first electrode and the second electrode may be referred to the relevant descriptions mentioned above, which will not be repeated herein.

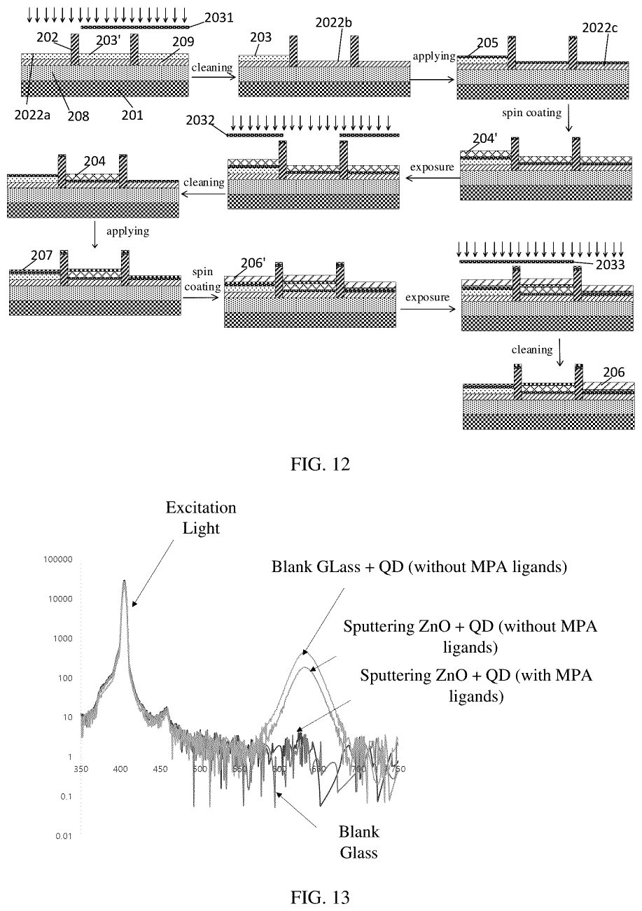

For example, FIG. 12 is a schematic diagram of a manufacturing process of an electroluminescent device provided by at least one embodiment of the present disclosure. As illustrated in FIG. 12, a first electrode 208 is formed on a base substrate 201, and a pixel definition layer 202 is formed on the first electrode 208. The pixel definition layer 202 includes a plurality of openings to form a first sub-pixel region 2022a, a second sub-pixel region 2022b and a third sub-pixel region 2022c spaced apart from each other, and a first functional layer 209 and a first color quantum dot material 203′ are formed in the first sub-pixel region 2022a, the second sub-pixel region 2022b and the third sub-pixel region 2022c. The second sub-pixel region 2022b and the third sub-pixel region 2022c are blocked by a first mask 2031, so that the light is irradiated to the first sub-pixel region 2022a, so that the first color quantum dot material 203′ in the first sub-pixel region 2022a undergoes a cross-linking reaction, that is, an exposure process to the first color quantum dot material 203′ in the first sub-pixel region 2022a is completed; and the first color quantum dot material 203′ that has not undergone the cross-linking reaction is cleaned to remove the first color quantum dot material 203′ in the second sub-pixel region 2022b and the third sub-pixel region 2022c, that is, a first color quantum dot layer 203 is formed. A first auxiliary layer 205 is formed in the first sub-pixel region 2022a, the second sub-pixel region 2022b and the third sub-pixel region 2022c, and formed on the side of the pixel definition layer 202 away from the base substrate 201, that is, the first auxiliary layer 205 is formed as a whole layer. Spin-coating a second color quantum dot material 204′ in the first sub-pixel region 2022a, the second sub-pixel region 2022b and the third sub-pixel region 2022c, and patterning the second color quantum dot material 204′ includes: using a second mask 2032 to block the first sub-pixel region 2022a and the third sub-pixel region 2022c, so that the light is irradiated to the second sub-pixel region 2022b, so that the second color quantum dot material 204′ in the second sub-pixel region 2022b undergoes the cross-linking reaction, that is, the exposure process to the second color quantum dot material 204′ is completed; and the second color quantum dot material 204′ that has not undergone the cross-linking reaction is cleaned to remove the second color quantum dot material 204′ in the first sub-pixel region 2022a and the third sub-pixel region 2022c, that is, a second color quantum dot layer 204 is formed. A second auxiliary layer 207 is formed in the first sub-pixel region 2022a, the second sub-pixel region 2022b and the third sub-pixel region 2022c, and formed on the side of the pixel definition layer 202 away from the base substrate 201, that is, the second auxiliary layer 207 is formed as a whole layer. A third color quantum dot material 206′ is spin-coated in the first sub-pixel region 2022a, the second sub-pixel region 2022b and the third sub-pixel region 2022c, and the patterning process on the third color quantum dot material 206′ includes: using a third mask 2033 to block the first sub-pixel region 2022a and the second sub-pixel region 2022b, so that the light is irradiated to the third sub-pixel region 2022c, so that the third color quantum dot material 206′ in the third sub-pixel region 2022c undergoes the cross-linking reaction, that is, the exposure process to the third color quantum dot material 206′ is completed; and the third color quantum dot material 206′ that has not undergone the cross-linking reaction is cleaned to remove the third color quantum dot material 206′ in the first sub-pixel region 2022a and the second sub-pixel region 2022b, that is, a third color quantum dot layer 206 is formed.

It should be noted that although not illustrated in FIG. 12, the first color quantum dot material 203′, the second color quantum dot material 204′ and the third color quantum dot material 206′ are also formed on the pixel definition layer 202.

For example, in one example, the first color quantum dot layer 203, the second color quantum dot layer 204 and the third color quantum dot layer 206 may be respectively a red quantum dot layer, a green quantum dot layer and a blue quantum dot layer, and the embodiments of the present disclosure do not limit to this. The first auxiliary layer 205 can prevent the second color quantum dot material formed later from remaining on the first color quantum dot layer, and the second auxiliary layer 207 can prevent the third color quantum dot material formed later from remaining on the second color quantum dot layer and the first color quantum dot layer, thereby avoiding the problem of color mixing and improving the color gamut of the quantum dot electroluminescent device.

For example, FIG. 13 is a graph of emission peaks of blank glass, blank glass with quantum dots (without MPA ligands), blank glass with zinc oxide and quantum dots (without MPA ligands) and blank glass with zinc oxide and quantum dots (with MPA ligands) under the irradiation of 400 nm excitation light. As illustrated in FIG. 13, under the irradiation of 400 nm excitation light, the blank glass has no emission peak: under the irradiation of 400 nm excitation light, and in the case where the blank glass is provided with quantum dots (without MPA ligands), the blank glass has an emission peak: Under the irradiation of 400 nm excitation light, and in the case where the blank glass is provided with zinc oxide and quantum dots (with MPA ligands), the blank glass has no emission peak, which shows that when the surface of the quantum dot has MPA ligands and contains zinc oxide, the quantum dot material formed later has basically no residue on the previously formed quantum dot layer. It should be noted that the MPA ligands are mercaptopropionic acid ligands.

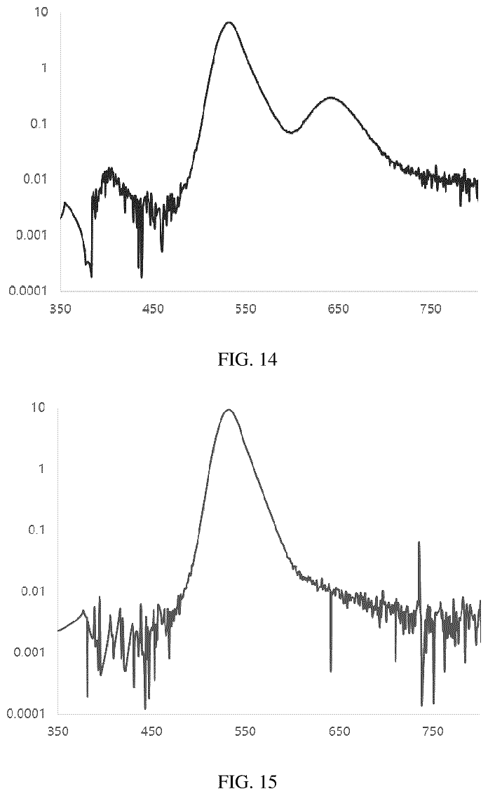

For example, FIG. 14 is a schematic diagram of an emission peak formed by red quantum dots (without MPA ligands) under the irradiation of 400 nm excitation light after sputtering ZnO and after development. In the case where the red quantum dots (without MPA ligands) are developed (washing off the red quantum dots) after sputtering ZnO and depositing, and then the green quantum dots are deposited to manufacture the device, a red emission peak is detected after the device emits light, indicating that the red quantum dots are residual and not fully developed. In contrast, in the case where the red quantum dots (with MPA ligands) are developed (washing off the red quantum dots) after sputtering ZnO and depositing, and then the green quantum dots are deposited to manufacture the device, no red emission peak is detected after the device emits light, indicating that there is no residue of the red quantum dots, and the development is complete.

For example, FIG. 15 is a schematic diagram of an emission peak formed by red quantum dots (with MPA ligands) under the irradiation of 400 nm excitation light after sputtering ZnO, developing (washing off the red quantum dots), and then depositing green quantum dots. As illustrated in FIG. 15, no red emission peak is detected after the device emits light, indicating that there is no residue of red quantum dots, and the development is complete.

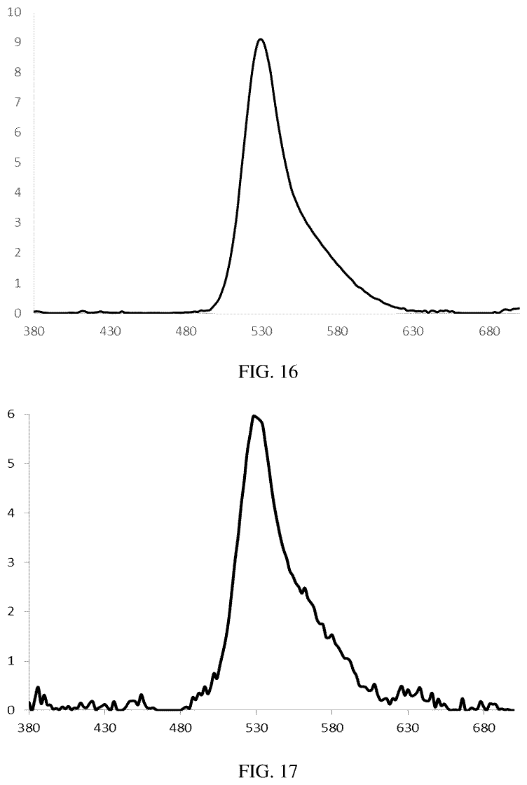

For example, FIG. 16 is a schematic diagram of an emission peak formed by green quantum dots (with MPA ligands) under the irradiation of 400 nm excitation light after sputtering ZnO and after development. As illustrated in FIG. 16, the green quantum dots are used to manufacture the device after sputtering ZnO and depositing, and no red signal was detected after the device emits light.

For example, FIG. 17 is a schematic diagram of green quantum dots emitting light after sputtering ZnO, depositing, exposure crosslinking, and then depositing red quantum dots (without MPA ligands) and developing (washing off the red quantum dots). As illustrated in FIG. 17, a red signal can be detected, which proves that there are red quantum dots remaining on the cross-linked green quantum dots.

The display substrate, the electroluminescent device and the manufacturing method thereof provided by at least one embodiment of the present disclosure have at least one of the following beneficial technical effects:
(1) In the display substrate provided by at least one embodiment of the present disclosure, the first auxiliary layer can prevent the second color quantum dot material formed later from remaining on the first color quantum dot layer, thereby avoiding the problem of color mixing to improve the color gamut of the finally formed electroluminescent device including the display substrate.
(2) In the display substrate provided by at least one embodiment of the present disclosure, the second auxiliary layer can prevent the third color quantum dot material formed later from remaining on the second color quantum dot layer and the first color quantum dot layer, thereby avoiding the problem of color mixing to improve the color gamut of the finally formed electroluminescent device including the display substrate.

The following statements should be noted:
(1) The drawings involve only the structure(s) in connection with the embodiment(s) of the present disclosure, and other structure(s) can be referred to common design(s).
(2) For clarity, in the drawings used to describe the embodiments of the present disclosure, the thicknesses of layers or regions are enlarged or reduced, that is, the drawings are not drawn to actual scale.
(3) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1. A display substrate, comprising:
a base substrate;
a pixel definition layer, disposed on the base substrate, wherein the pixel definition layer comprises a plurality of openings, the plurality of openings correspond to a plurality of sub-pixel regions, and the plurality of sub-pixel regions at least comprise a first sub-pixel region and a second sub-pixel region;
a first color quantum dot layer, disposed in the first sub-pixel region;
a second color quantum dot layer, disposed in the second sub-pixel region; and
a first auxiliary layer, at least comprising a first portion and a second portion spaced apart from each other, wherein the first portion is disposed on a side of the first color quantum dot layer away from the base substrate, and the second portion is disposed on a side of the second color quantum dot layer close to the base substrate.

2. The display substrate according to claim 1, wherein the first portion has a same thickness as that of the second portion, and a material of the first portion is the same as a material of the second portion.

3. The display substrate according to claim 2, wherein the material of the first portion and the material of the second portion are metal oxides.

4. The display substrate according to claim 3, wherein a surface roughness of each of the metal oxides is less than 3 nm.

5. The display substrate according to claim 1, wherein the first auxiliary layer further comprises a third portion, the third portion is disposed on a side of the pixel definition layer away from the base substrate, and the first portion, the second portion and the third portion are not connected to each other.

6. The display substrate according to claim 5, further comprising a second auxiliary layer and a third color quantum dot layer disposed in a third sub-pixel region,
wherein the second auxiliary layer is at least disposed on a side of the second color quantum dot layer away from the base substrate.

7. The display substrate according to claim 6, wherein a material of the first auxiliary layer is different from a material of the second auxiliary layer.

8. The display substrate according to claim 7, wherein the material of the first auxiliary layer comprises an electron-transporting type oxide, the material of the second auxiliary layer comprises a hole-transporting type oxide, at least a part of the first auxiliary layer is in contact with the first color quantum dot layer, and at least a part of the second auxiliary layer is in contact with the third color quantum dot layer.

9. (canceled)

10. (canceled)

11. (canceled)

12. The display substrate according to claim 6, wherein the second auxiliary layer at least comprises a fourth portion, a fifth portion and a sixth portion spaced apart from each other, and the fourth portion is disposed on a side of the first portion away from the base substrate, and is at least partially in contact with the first portion;
the fifth portion is disposed on a side of the second color quantum dot layer away from the base substrate; and
the sixth portion is disposed on a side of the third color quantum dot layer close to the base substrate.

13. The display substrate according to claim 12, wherein the second auxiliary layer further comprises a seventh portion spaced apart from the fourth portion, the fifth portion, and the sixth portion, and the seventh portion is disposed on a side of the third portion away from the base substrate, and is at least partially in contact with the third portion.

14. The display substrate according to claim 13, wherein the first auxiliary layer further comprises an eighth portion spaced apart from the first portion, the second portion, and the third portion, and the eighth portion is disposed on a side of the sixth portion close to the base substrate.

15. (canceled)

16. (canceled)

17. The display substrate according to claim 6, wherein
the first auxiliary layer comprises a first layer structure and a second layer structure which are stacked, the first layer structure is on a side of the second layer structure close to the base substrate, and a material of the first layer structure comprises at least one of an electron-transporting type oxide and a hole-transporting type oxide;
a general formula of the second layer structure comprises 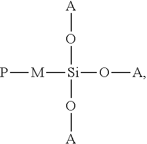
wherein A is —(CH₂)ₙCH₃, n is less than or equal to 4, M is —(CH₂)ₓ, and x is less than or equal to 6; and P comprises at least one of

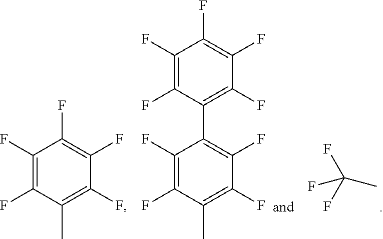

18. The display substrate according to claim 17, wherein the second auxiliary layer comprises a third layer structure and a fourth layer structure which are stacked, the third layer structure is on a side of the fourth layer structure close to the base substrate, and a material of the third layer structure comprises at least one of an electron-transporting type oxide and a hole-transporting type oxide;
a general formula of the fourth layer structure comprises 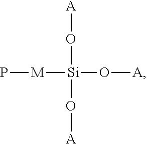
wherein A is —(CH₂)ₙCH₃, n is less than or equal to 4, M is —(CH₂)ₓ, and x is less than or equal to 6; and P comprises at least one of

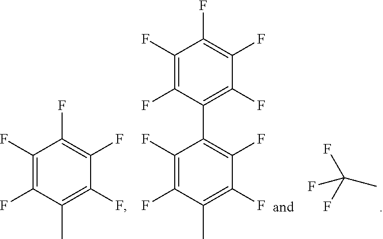

19. (canceled)

20. An electroluminescent device, comprising the display substrate according to claim 1, and a first electrode and a first functional layer laminated on the base substrate, wherein the first electrode is disposed on a side of the first functional layer close to the base substrate; and
the first functional layer and the first electrode are laminated in the plurality of sub-pixel regions, and the first functional layer and the first electrode which are stacked are between the first color quantum dot layer and the base substrate, between the second color quantum dot layer and the base substrate, and between the third color quantum dot layer and the base substrate.

21. The electroluminescent device according to claim 20, wherein a material the first auxiliary layer is the same as a material of the first functional layer, and in a direction perpendicular to a main surface of the base substrate, a thickness of the first functional layer is 4 times to 5 times of a thickness of the first auxiliary layer.

22. The electroluminescent device according to claim 20, wherein a thickness of the first color quantum dot layer is 4 times to 5 times of a thickness of the first auxiliary layer.

23. A manufacturing method of an electroluminescent device, comprising:
providing a base substrate;
forming a pixel definition layer on the base substrate, wherein the pixel definition layer comprises a plurality of openings to form a plurality of sub-pixel regions spaced apart from each other, and the plurality of sub-pixel regions at least comprise a first sub-pixel region and a second sub-pixel region;
forming a first color quantum dot layer in the first sub-pixel region; and
forming a second color quantum dot layer in the second sub-pixel region;
the manufacturing method further comprises: forming a first auxiliary layer after forming the first color quantum dot layer and before forming the second color quantum dot layer, wherein the first auxiliary layer at least comprises a first portion and a second portion spaced apart from each other, the first portion is disposed on a side of the first color quantum dot layer away from the base substrate, and the second portion is disposed on a side of the second color quantum dot layer close to the base substrate.

24. The manufacturing method according to claim 23, wherein before forming the first color quantum dot layer, the manufacturing method further comprises forming a first functional layer on the base substrate, and in the second sub-pixel region and a third sub-pixel region, the first functional layer and the first auxiliary layer are attached to each other.

25. (canceled)

26. The manufacturing method according to claim 23, wherein forming the first auxiliary layer comprises forming a first layer structure and a second layer structure which are stacked, the first layer structure is on a side of the second layer structure close to the base substrate, and forming the first layer structure comprises applying at least one of an electron-transporting type oxide and a hole-transporting type oxide on the base substrate by a method of magnetron sputtering; and
forming the second layer structure comprises placing the base substrate formed with the first layer structure in a solution of a silane coupling agent for soaking, and the solution of the silane coupling agent comprises a first group containing a perfluoro terminal.

27. The manufacturing method according to claim 24, further comprising:
forming a second auxiliary layer at least on a side of the second color quantum dot layer away from the base substrate; and
forming a third color quantum dot layer on a side of the second auxiliary layer away from the base substrate and in the third sub-pixel region,
wherein a material of the first auxiliary layer is different from a material of the second auxiliary layer.

28. (canceled)

29. (canceled)

30. (canceled)

31. (canceled)

32. (canceled)

33. (canceled)

34. (canceled)
